(19) United States
(12) Patent Application Publication
(10) Pub. No.: US 2026/0039975 A1
(43) Pub. Date: Feb. 5, 2026

(54) PHOTOELECTRIC CONVERSION APPARATUS AND EQUIPMENT

(71) Applicant: CANON KABUSHIKI KAISHA, Tokyo (JP)

(72) Inventors: DAISUKE KOBAYASHI, Kanagawa (JP); TOMOYA KUMAGAI, Tokyo (JP)

(21) Appl. No.: 19/273,798

(22) Filed: Jul. 18, 2025

(30) Foreign Application Priority Data
Jul. 30, 2024 (JP) 2024-123115

(51) Int. Cl. H04N 25/77; H10F 39/00

(52) U.S. Cl. CPC H04N 25/77; H10F 39/809

(57) ABSTRACT

A photoelectric conversion apparatus includes a plurality of pixels, wherein each pixel of the plurality of pixels includes, a photoelectric conversion element, a first amplification unit including an input node to which a signal from the photoelectric conversion element is input, the first amplification unit configured to output a signal obtained by amplifying a signal level of the input node, a holding capacitor section configured to hold the output signal of the first amplification unit and have a variable capacitance, and a second amplification unit including a second input node to which a signal output from the holding capacitor section is input, the second amplification unit configured to output a signal obtained by amplifying a signal level of the second input node, wherein the capacitance of the holding capacitor section is changed based on a change in driving power of at least one of the first and second amplification units.

### BACKGROUND

### Field of the Technology

The present invention relates to a photoelectric conversion apparatus and equipment.

### DESCRIPTION OF THE RELATED ART

There have been discussions about photoelectric conversion apparatuses that perform a global electronic shutter operation of simultaneously resetting photoelectric conversion units disposed in respective pixels and reading out charges from the photoelectric conversion units. Japanese Patent Application Laid-Open Publication No. 2023-83030 discusses an imaging apparatus having a voltage-holding global electronic shutter function of converting signal charges into voltages and holding the voltages. The imaging apparatus discussed in Japanese Patent Application Laid-Open Publication No. 2023-83030 implements the global electronic shutter operation by simultaneously holding signal voltages generated by the photoelectric conversion units of all pixels in capacitive elements and then sequentially reading out the held voltages. Japanese Patent Application Laid-Open Publication No. 2023-83030 discusses increasing the size of the capacitive elements in red (R) pixels where an R optical filter is disposed and the amount of incident light is relatively small, compared to the size of the capacitive elements in green (G) pixels where a G optical filter is disposed and the amount of incident light is relatively large.

Japanese Patent Application Laid-Open Publication No. 2023-83030 does not take into account the relationship between the size setting of the capacitive elements and the signal settling time, and there is room for further improvement in the precision of signals held in the capacitive elements and imaging performance.

### SUMMARY

According to an aspect of the present disclosure, a photoelectric conversion apparatus includes a plurality of pixels, and a processing circuit configured to process signals read from the plurality of pixels, wherein each pixel of the plurality of pixels includes, a photoelectric conversion element, a first amplification unit including an input node to which a signal from the photoelectric conversion element is input, the first amplification unit being configured to output a signal obtained by amplifying a signal level of the input node, a holding capacitor section configured to hold the output signal of the first amplification unit and have a variable capacitance, and a second amplification unit including a second input node to which a signal output from the holding capacitor section is input, the second amplification unit being configured to output a signal obtained by amplifying a signal level of the second input node, wherein the capacitance of the holding capacitor section is changed based on a change in driving power of at least one of the first and second amplification units.

According to another aspect of the present disclosure, a photoelectric conversion apparatus includes a plurality of pixels; and a processing circuit configured to process signals read from the plurality of pixels, wherein each pixel of the plurality of pixels includes a photoelectric conversion element, a first amplification unit including an input node to which a signal from the photoelectric conversion element is input, the first amplification unit being configured to output a signal obtained by amplifying a signal level of the input node, and a holding capacitor section configured to hold the output signal of the first amplification unit and have a variable capacitance, and wherein the capacitance of the holding capacitor section is changed based on a change in driving power of the first amplification unit.

According to yet another aspect of the present disclosure, a photoelectric conversion apparatus includes a plurality of pixels; and a processing circuit configured to process signals read from the plurality of pixels, wherein each pixel of the plurality of pixels includes a photoelectric conversion element, a first amplification unit including an input node to which a signal from the photoelectric conversion element is input, the first amplification unit being configured to output a signal obtained by amplifying a signal level of the input node, and a holding capacitor section connected to the first amplification unit via a switch and configured to hold the output signal of the first amplification unit and have a variable capacitance, and wherein the capacitance of the holding capacitor section is changed based on a change in an on period of the switch.

In a further aspect of the present disclosure there is provided equipment comprising a photoelectric conversion apparatus according to any other aspect of the present disclosure and comprising at least one of: an optical apparatus, a processing apparatus, a processing apparatus, a display apparatus, a storage apparatus, and a mechanical apparatus.

Optional features for the aspects of the present disclosure are provided in claims 2 to 19.

Features of the present disclosure will become apparent from the following description of embodiments with reference to the attached drawings. The following description of embodiments is described by way of example.

### BRIEF DESCRIPTION OF THE DRAWINGS

FIG. 1 is a block diagram for describing a photoelectric conversion apparatus according to a first embodiment.

FIG. 2 is a schematic diagram for describing the photoelectric conversion apparatus according to the first embodiment.

FIG. 3 is a circuit diagram for describing the photoelectric conversion apparatus according to the first embodiment.

FIG. 4 is a circuit diagram of current sources in the photoelectric conversion apparatus according to an embodiment.

FIG. 5 is a circuit diagram of a signal holding memory in the photoelectric conversion apparatus according to an embodiment.

FIG. 6 is a driving timing chart of the photoelectric conversion apparatus according to the first embodiment.

FIG. 7 is a schematic cross-sectional view for describing the photoelectric conversion apparatus according to the first embodiment.

FIG. 8 is a schematic cross-sectional view illustrating another example of the photoelectric conversion apparatus according to the first embodiment.

FIG. 9 is a schematic plan view of the signal holding memory in the photoelectric conversion apparatus according to the first embodiment.

FIG. 10 is a schematic plan view of the signal holding memory, illustrating another example of the photoelectric conversion apparatus of the first embodiment.

FIG. 11 is a circuit diagram of a signal holding memory in a photoelectric conversion apparatus according to a second embodiment.

FIG. 12 is a driving timing chart of the photoelectric conversion apparatus according to the second embodiment.

FIG. 13 is a schematic plan view of the signal holding memory in the photoelectric conversion apparatus according to the second embodiment.

FIG. 14 is a circuit diagram of a signal holding memory in a photoelectric conversion apparatus according to a third embodiment.

FIG. 15 is a schematic plan view of the signal holding memory in the photoelectric conversion apparatus according to the third embodiment.

FIGS. 16A to 16C are schematic diagrams for describing equipment according to a fourth embodiment.

### DESCRIPTION OF THE EMBODIMENTS

Embodiments described below are intended for implementation of the technical concept of the present invention and not to limit the present invention. Sizes and positional relationships of members illustrated in the drawings may be exaggerated for the sake of clear description. In the following description, similar components are denoted by the same reference numerals, and a description thereof may be omitted.

The embodiments of the present invention will be described in detail below with reference to the drawings. In the following description, terms expressing specific directions or positions (such as "up", "down", "right", and "left", and other terms including these words) are used as appropriate. The use of such terms is intended to facilitate the understanding of the embodiments with reference to the drawings, and the technical scope of the present invention shall not be limited by the meanings of the terms.

As employed herein, a "plane" refers to a surface in a direction parallel to a main surface of a substrate. The main surface of a substrate can be a light incident surface of a substrate including photoelectric conversion elements, a surface where a plurality of analog-to-digital converters (ADCs) are repeatedly disposed, or a bonding surface between substates of a stacked photoelectric conversion apparatus. A "plan view" refers to a view in a direction perpendicular to the light incident surface of a semiconductor layer. A "cross section" refers to a surface of a semiconductor layer in a direction perpendicular to the light incident surface. A "cross-sectional view" refers to a view in a direction perpendicular to the light incident surface of a semiconductor layer. If the light incident surface of a semiconductor layer is a microscopically rough surface, a plan view is defined with reference to the light incident surface of the semiconductor layer when viewed macroscopically.

In the following embodiments, an imaging apparatus will mainly be described as an example of a photoelectric conversion apparatus. However, the embodiments are not limited to imaging apparatuses and can also be applied to other examples of the photoelectric conversion apparatus. Examples include ranging apparatuses (apparatuses for measuring a distance using focus detection or time of flight [ToF]) and metering apparatuses (apparatuses for measuring the amount of incident light).

Metal members described herein, such as wiring and pads, may be made of a single-element metal alone or a mixture (alloy). For example, wiring described as copper wiring may be composed of copper alone, or may have a composition that mainly contains copper and further includes other components. For example, pads to be connected to external terminals may be composed of aluminum alone, or may have a composition that mainly contains aluminum and further includes other components. The copper wiring and aluminum pads described here are merely examples, and may be replaced with various metals. The wiring and pads described here are examples of metal members used in the photoelectric conversion apparatus, and can be applied to other metal members as well.

In the following description, charges for photoelectric conversion units in pixels to accumulate are electrons. Transistors included in the pixels are all N-channel metal-oxide-semiconductor (MOS) transistors (hereinafter, abbreviated as NMOS transistors). However, the charges for the photoelectric conversion units to accumulate may be holes, in which case the transistors in the pixels may be P-channel MOS transistors (hereinafter, abbreviated as PMOS transistors). In other words, the conductivity types of the transistors can be changed as appropriate depending on the polarity of the charges to be handled as signals.

In the following embodiments, connections between circuit elements may be described. In such a case, even if there is another element interposed between elements of interest, the elements of interest are regarded as being connected to each other unless otherwise specified. Suppose, for example, that an element A is connected to one of nodes of a capacitive element C, and an element B is connected to the other node. Even in such a case, the elements A and B are regarded as being connected to each other unless otherwise specified.

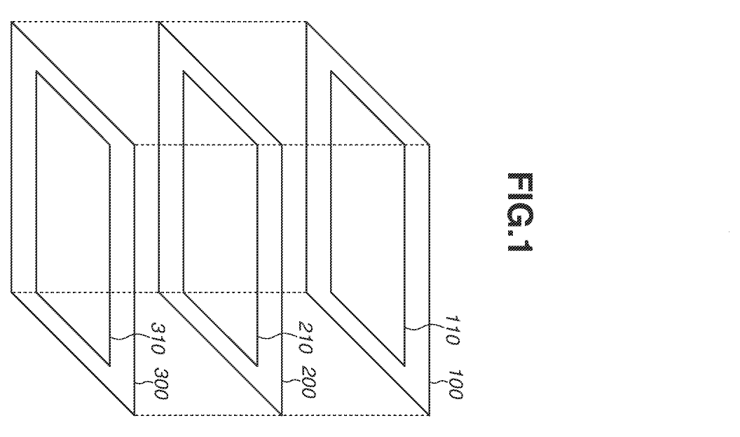

A photoelectric conversion apparatus according to a first embodiment of the present invention will be described with reference to FIGS. 1 to 10.

FIG. 1 is an example of a schematic diagram illustrating the photoelectric conversion apparatus according to the present embodiment.

As illustrated in FIG. 1, a photoelectric conversion apparatus 10 includes three substrates, namely, a first substrate 100, a second substrate 200, and a third substrate 300. The photoelectric conversion apparatus 10 has a three-dimensional structure formed by laminating these three substrates. The first substrate 100, the second substrate 200, and the third substrate 300 are stacked in this order. More substrates may further be stacked. While the photoelectric conversion apparatus 10 including a stack of a plurality of substrates is described below as an example, a single substrate on which the components included in the first, second, and third substrates 100, 200, and 300 are disposed may be used as the photoelectric conversion apparatus.

The first substrate 100 includes a pixel region 110 where a plurality of pixels are arranged in a two-dimensional array as seen in a plan view. The second substrate 200 includes a memory region 210 where a plurality of pixel memories are arranged in a two-dimensional array as seen in a plan view. The third substrate 300 includes a signal processing section 310 where a plurality of signal processing circuits are disposed.

The first, second, and third substrates 100, 200, and 300 may each be a semiconductor layer such as a silicon substrate. The first, second, and third substrates 100, 200, and 300 may each include a semiconductor layer and a wiring structure. Each substrate may be a chip or a wafer. The photoelectric conversion apparatus 10 includes a plurality of metal bonding portions where metal members of a top layer (first bonding layer) that is the wiring layer located closest to the second substrate 200 in the wiring structure of the first substrate 100 are bonded to metal members of a top layer (second bonding layer) that is the wiring layer located closest to the first substrate 100 in the wiring structure of the second substrate 200. The bonding surface where the plurality of metal bonding portions are located includes insulative bonding portions where insulating members of the first bonding layer and insulating members of the second bonding layer are bonded. The second and third substrates 200 and 300 are also bonded by a bonding structure similar to that of the first and second substrates 100 and 200. Such mutual bonding of the metal members disposed on the substrates 100, 200, and 300 enables signal exchange between the members.

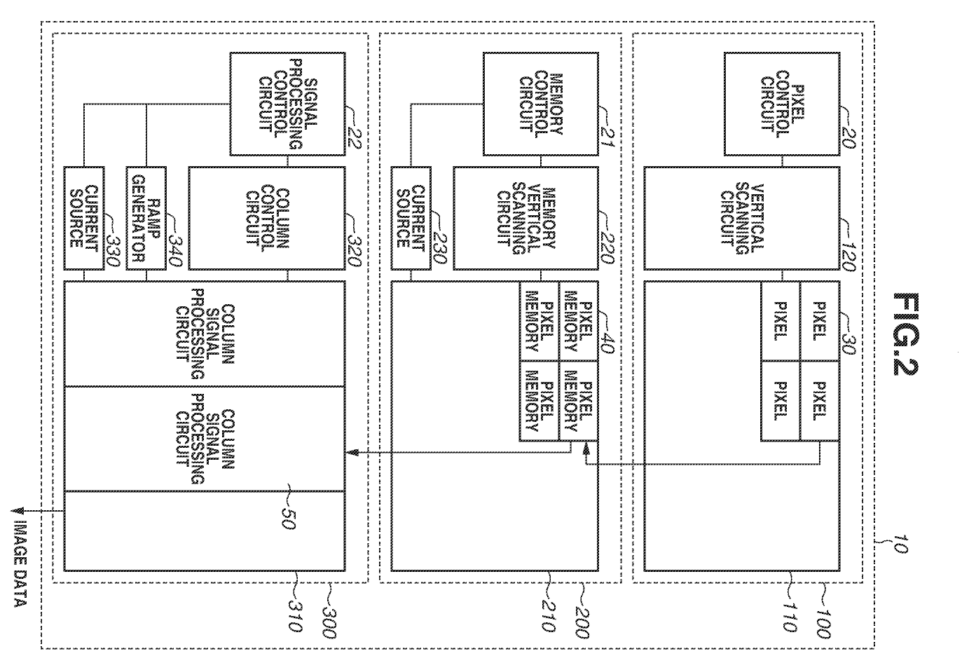

FIG. 2 is an example of a block diagram of the photoelectric conversion apparatus 10 according to the present embodiment.

The first substrate 100 includes the pixel region 110, a vertical scanning circuit 120, and a pixel control circuit 20. The pixel region 110 includes a plurality of pixels 30 for performing photoelectric conversion. The plurality of pixels 30 are arranged in an array set out in a plurality of rows and a plurality of columns within the pixel region 110. The pixels 30 include photoelectric conversion elements such as photodiodes. The photoelectric conversion elements may be a photoelectric conversion film. The photoelectric conversion elements generate and accumulate signal charges corresponding to incident light. The pixels 30 output pixel signals corresponding to the amounts of the signal charges. The pixel signals output from the pixels 30 are analog signals.

Aside from effective pixels that output pixel signals corresponding to the amount of incident light, optical black pixels where photoelectric conversion elements are shielded from light and pixels that do not output a signal may also be disposed in the pixel region 110. As employed herein, the horizontal direction in the diagrams will be referred to as a row direction, and the vertical direction a column direction. The number of rows and the number of columns of the pixel array disposed in the pixel region 110 are not limited in particular.

The pixel control circuit 20 is a logic circuit that generates timing to operate the pixels 30, and outputs driving pulses for the pixels 30 to the vertical scanning circuit 120. The vertical scanning circuit 120 includes drivers for driving the pixels 30 row by row. A voltage SVDD that is a power supply voltage to be supplied to the pixels 30 and a reference voltage SGND may be supplied via pads and metal bonding portions, or via the pixel control circuit 20.

The second substrate 200 includes the memory region 210, a memory vertical scanning circuit 220, a current source 230, and a memory control circuit 21. Pixel memories 40 are arranged in an array set out in a plurality of rows and a plurality of columns within the memory region 210. The pixel memories 40 have a function of holding the pixel signals output from the pixels 30. The number of pixels 30 included in the pixel region 110 and the number of pixel memories 40 included in the memory region 210 do not need to be the same. For example, the pixel memories 40 do not need to be provided for dummy pixels that do not output a signal. Dummy pixel memories that do not hold a signal may be disposed corresponding to the dummy pixels.

The current source 230 supplies a reference current to the pixel memories 40. The memory control circuit 21 includes a logic circuit that generates timing to operate the pixel memories 40 and controls circuits disposed near the pixels, such as the current source 230. Driving pulses output from the memory control circuit 21 are input to the memory vertical scanning circuit 220. The memory vertical scanning circuit 220 includes drivers for driving the pixel memories 40 row by row. A voltage MVDD that is a power supply voltage to be supplied to the pixel memories 40 and a reference voltage MGND may be supplied via pads and metal bonding portions, or via the memory control circuit 21.

The third substrate 300 includes the signal processing section 310, a column control circuit 320, a ramp generator 340, a current source 330, and a signal processing control circuit 22. The signal processing section 310 includes column signal processing circuits 50 arranged in an array in the column direction. The column signal processing circuits 50 perform analog-to-digital (AD) conversion on signal voltages output from the pixel memories 40, based on a reference voltage generated by the ramp generator 340. The column signal processing circuits 50 then output the AD-converted signals to the outside of the third substrate 300. In the present embodiment, ramp AD conversion is described as an example of the AD conversion method. However, the AD conversion method is not limited to the ramp AD conversion. For example, AD conversion methods such as successive approximation AD conversion, cyclic AD conversion, and ΔΣ AD conversion can be employed. The column signal processing circuits 50 may perform digital processing such as noise processing on image data.

The current source 330 supplies a reference current to the column signal processing circuits 50. The signal processing control circuit 22 includes a logic circuit that generates timing to operate the column signal processing circuits 50 and configures function settings of the ramp generator 340 and the current source 330. Driving pulses output from the signal processing control circuit 22 are input to the column control circuit 320. The column control circuit 320 includes a driver that outputs driving pulses to the column signal processing circuits 50. A voltage AVDD that is a power supply voltage to be supplied to the column signal processing circuits 50 and a reference voltage AGND may be supplied via pads and metal bonding portions, or via the signal processing control circuit 22.

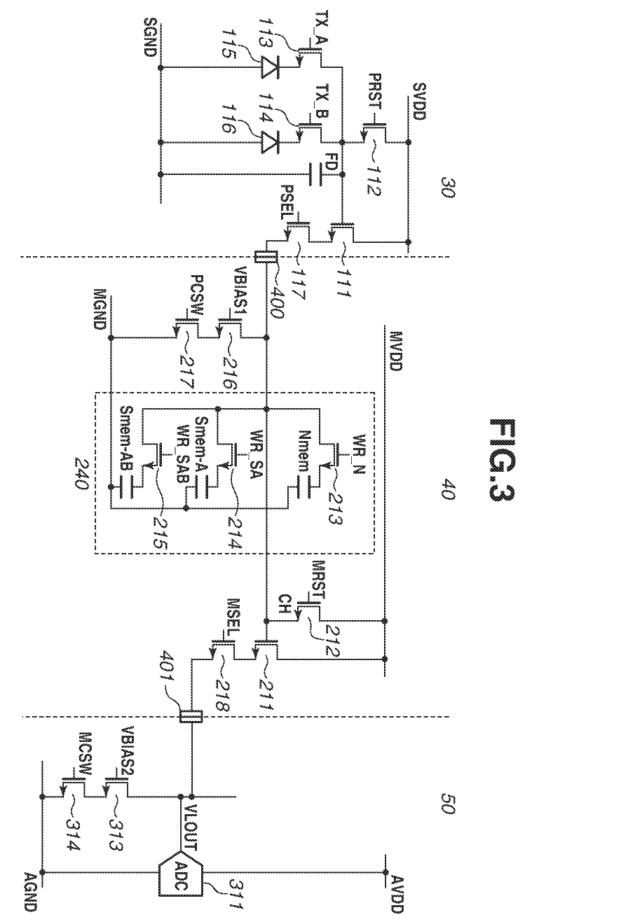

The photoelectric conversion apparatus according to the present embodiment is a photoelectric conversion apparatus that performs a voltage-domain global electronic shutter operation. The reading of the pixels 30 in the photoelectric conversion apparatus 10 according to the present embodiment will be described with reference to FIGS. 3 to 5.

FIG. 3 is an example of a circuit diagram of a pixel 30, a pixel memory 40, and a column signal processing circuit 50 included in the photoelectric conversion apparatus 10 according to the present embodiment.

The pixel 30 includes a photoelectric conversion element (photodiode [PD]) 115, a PD 116, a transfer transistor 113 (pixel transfer transistor), a transfer transistor 114 (pixel transfer transistor), and a reset transistor 112 (pixel reset transistor). The pixel 30 further includes an amplification transistor 111 (first amplification unit, or pixel amplification transistor), a selection transistor 117 (pixel selection transistor), and a floating diffusion (FD) capacitor portion. The FD capacitor portion is the input node of the amplification transistor 111 that is the first amplification unit. Signals from the PDs 115 and 116 are input to the amplification transistor 111. The amplification transistor 111 outputs a signal obtained by amplifying the signal level of this input node. As employed herein, "amplification" covers both cases where the gain is greater than or equal to 1x and where the gain is less than 1x. The amplification transistor 111 operates as a source-follower circuit. Typically, the amplification transistor 111 has a gain in the range of 0.8x to 1x.

The photoelectric conversion apparatus 10 according to the present embodiment includes the PDs 115 and 116 in a single pixel 30. The photoelectric conversion apparatus 10 is an image plane phase-difference detection photoelectric conversion apparatus that uses the signals of the PDs 115 and 116 for phase difference detection. The anode terminal of the PD 115 is connected to the reference voltage SGND, and the cathode terminal is connected to the source of the transfer transistor 113. The anode terminal of the PD 116 is connected to the reference voltage SGND, and the cathode terminal is connected to the source of the transfer transistor 114. The drain of the transfer transistor 113 and the drain of the transfer transistor 114 are both connected to the gate of the amplification transistor 111 and the source of the reset transistor 112. The FD capacitor portion is connected the gate of the amplification transistor 111 with the reference voltage SGND as a reference. The FD capacitor portion functions as a charge-voltage conversion unit that temporarily holds the signal charges generated by the PDs 115 and 116 and converts the held signal charges into a voltage signal. The drains of the reset transistor 112 and the amplification transistor 111 are connected to the power supply wiring of the reference voltage SVDD. The source of the amplification transistor 111 is connected to the drain of the selection transistor 117.

The configuration of the pixel 30 illustrated in FIG. 3 is merely an example, and transistors may be further included. For example, a transistor for changing the capacitance of the FD capacitor portion and/or a transistor for draining the signal charge from the photoelectric conversion element 115 may further be included. The pixel 30 may be configured without the selection transistor 117, so that its selection and deselection states are switched by the voltage input from the reset transistor 112 to the FD capacitor portion.

The pixel memory 40 includes a holding capacitor section 240. The holding capacitor section 240 may include a plurality of capacitive elements and a plurality of write transistors. In the present embodiment, the holding capacitor section 240 includes a signal holding memory Nmem (first capacitive element), a signal holding memory Smem-A (second capacitive element) and a signal holding memory Smem-AB (third capacitive element) as a combination of a plurality of capacitive elements. The plurality of signal holding memories may hereinafter be referred to collectively as signal holding memories mem (holding capacitor section 240). The signal holding memory Nmem is connected to a memory write transistor 213. The signal holding memory Smem-A is connected to a memory write transistor 214. The signal holding memory Smem-AB is connected to a memory write transistor 215. The pixel memory 40 further includes a reset transistor 212, an amplification transistor 211, a current source transistor 216 (first current source transistor), a switch transistor 217, and a selection transistor 218. The reset transistor 212 is a memory reset transistor. The amplification transistor 211 is a memory amplification transistor. The selection transistor 218 is a memory selection transistor.

The source of the selection transistor 117 of the pixel 30 is connected to the drain of the current source transistor 216 of the pixel memory 40 via a metal bonding portion 400. The source of the current source transistor 216 is connected to the drain of the switch transistor 217. Here, a control signal VBIAS1 is supplied from the current source 230 to the gate of the current source transistor 216, whereby the flow of a current based on the control signal VBIAS1 is controlled. A configuration of the current source 230 will be described below.

The source of the selection transistor 218 is connected to the drain of a current source transistor 313 (second current source transistor) of the column signal processing circuit 50 via a metal bonding portion 401. The source of the current source transistor 313 is connected to the drain of a switch transistor 314. Here, a control signal VBIAS2 is supplied from the current source 330 to the current source transistor 313, whereby the flow of a current based on the control signal VBIAS2 is controlled.

Cu-Cu bonding (Cu-to-Cu bonding [CCB]) can be used for the metal bonding portions 400 and 401. This is not restrictive, and the first and second substrates 100 and 200, and the second and third substrates 200 and 300, may be electrically connected using through-silicon vias (TSVs).

One of the terminals of the signal holding memory Nmem is connected to power supply wiring for supplying the reference voltage MGND, and the other terminal is connected to the source of the memory write transistor 213. The drain of the memory write transistor 213 is connected to the gate of the amplification transistor 211 (second amplification unit). Similarly, one of the terminals of the signal holding memory Smem-A is connected to the power supply wiring for supplying the reference voltage MGND, and the other terminal is connected to the source of the memory write transistor 214. The drain of the memory write transistor 214 is connected to the gate of the amplification transistor 211. One of the terminals of the signal holding memory Smem-AB is connected to the power supply wiring for supplying the reference voltage MGND, and the other terminal is connected to the source of the memory write transistor 215. The drain of the memory write transistor 215 is connected to the gate of the amplification transistor 211. Here, the signal holding memories (capacitive elements) may be any elements having a signal-holding function.

For example, the capacitive elements may be capacitors formed in the wiring structure, or capacitors formed in a semiconductor layer such as a silicon substrate. Examples of the capacitors formed in the wiring structure include a dynamic random access memory (DRAM) and metal-insulator-metal (MIM) capacitor structures formed in the wiring structure. Examples of the capacitors formed in a semiconductor layer such as a silicon substrate include metal-insulator-semiconductor (MIS) capacitor structures formed of diffusion layers and polysilicon on the silicon substrate. The amplification transistor 211 operates as a source-follower circuit. Typically, the amplification transistor 211 has a gain in the range of 0.8x to 1x.

Each of the memory write transistors 213, 214, and 215 is typically formed in a semiconductor substrate such as a silicon substrate. If the signal holding memories (capacitive elements) are formed by a DRAM disposed in the wiring structure, the sources of the memory writ transistors 213, 214, and 215 are connected to the DRAM via contact plugs and wiring in the wiring structure.

The column signal processing circuit 50 includes an ADC 311, the current source transistor 313, and the switch transistor 314.

The source of the current source transistor 313 is connected to the drain of the switch transistor 314. The source of the switch transistor 314 is connected to power supply wiring for supplying the reference voltage AGND. Here, the control signal VBIAS2 is supplied from the current source 330 to the gate of the current source transistor 313, and a current based on the current signal VBIAS2 flows through the current source transistor 313. The drain of the current source transistor 313 is connected to the input of the ADC 311 via a signal line VLOUT. The ADC 311 is connected to power supply wiring for supplying the voltage AVDD and the power supply wiring for supplying the reference voltage AGND.

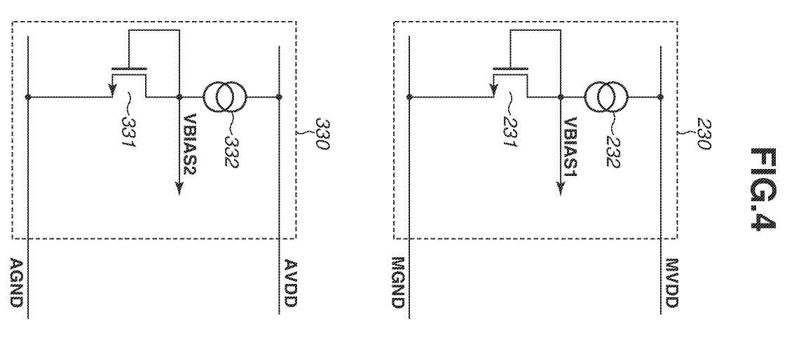

FIG. 4 illustrates a configuration example of the current sources 230 and 330. In FIG. 4, the switch transistors 217 and 314 illustrated in FIG. 3 are omitted.

The current source 230 constitutes a current mirror circuit with its reference current source 232 and bias generation transistor 231. The reference current source 232 that generates the reference current is connected between the power supply wiring for supplying the voltage MVDD and the drain of the bias generation transistor 231. The source of the bias generation transistor 231 is connected to the power supply wiring for supplying the reference voltage MGND. The control signal VBIAS1, which is generated by connecting the gate of the bias generation transistor 231 to the drain of the bias generation transistor 231, is supplied to the pixel memories 40.

The current source 330 constitutes a current mirror circuit with its reference current source 332 and bias generation transistor 331. The reference current source 332 for generating the reference current is connected between the power supply wiring for supplying the voltage MVDD and the drain of the bias generation transistor 331. The source of the bias generation transistor 331 is connected to the power supply wiring for supplying the reference voltage AGND. The control signal VBIAS2, which is generated by connecting the gate of the bias generation transistor 331 to the drain of the bias generation transistor 331, is supplied to the column signal processing circuits 50.

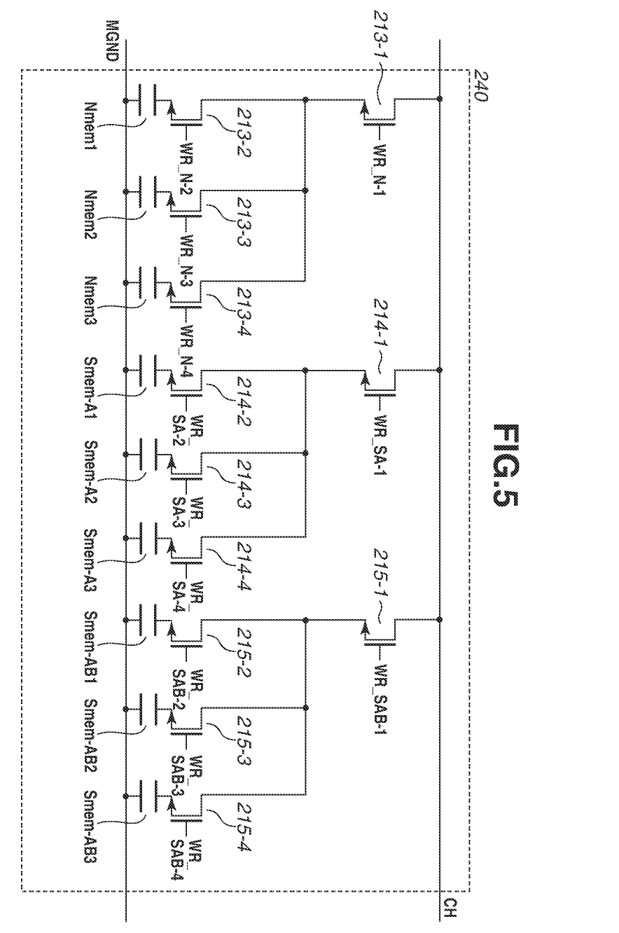

FIG. 5 is a diagram illustrating a detailed configuration of the holding capacitor section 240.

As illustrated in FIG. 5, the signal holding memory Nmem of FIG. 3 includes a plurality of signal holding memories Nmem1 to Nmem3. The memory write transistor 213 includes memory write transistors 213-1 to 213-4. The source of the memory write transistor 213-1 is connected to the drains of the memory write transistors 213-2 to 213-4. The drain of the memory write transistor 213-1 is connected to the gate of the amplification transistor 211. The plurality of signal holding memories Nmem1 to Nmem3 are connected to the power supply wiring for supplying the reference voltage MGND at one of their terminals each. The other terminal of each signal holing memory of the plurality of signal holding memories is connected to the sources of the respective memory write transistors 213-2 to 213-4.

Similarly, the signal holding memory Smem-A includes a plurality of signal holding memories Smem-A1 to Smem-A3. The memory write transistor 214 includes memory write transistors 214-1 to 214-4. The source of the memory write transistor 214-1 is connected to the drains of the memory write transistors 214-2 to 214-4. The drain of the memory write transistor 214-1 is connected to the gate of the amplification transistor 211. The plurality of signal holding memories Smem-A1 to Smem-A3 are connected to the power supply wiring for supplying the reference voltage MGND at one of their terminals each. The other terminal of each signal holding memories of the plurality of signal holding memories is connected to the sources of the respective memory write transistors 214-2 to 214-4.

The signal holding memory Smem-AB includes a plurality of signal holding memories Smem-AB1 to Smem-AB3. The memory write transistor 215 includes memory write transistors 215-1 to 215-4. The source of the memory write transistor 215-1 is connected to the drains of the memory write transistors 215-2 to 215-4. The drain of the memory write transistor 215-1 is connected to the gate of the amplification transistor 211. The plurality of signal holding memories Smem-AB1 to Smem-AB3 are connected to the power supply wiring for supplying the reference voltage MGND at one of their terminals each. The other terminal of each signal holding memories of the plurality of signal holding memories is connected to the sources of the respective memory write transistors 215-2 to 215-4.

The connections of the reference voltages are not limited to those described in the present embodiment. For example, the reference voltages SGND and MGND may be made common. The reference voltages MGND and AGND may be made common. As employed herein, "common" may cover configurations where the plurality of reference power supplies are connected to the outside of the photoelectric conversion apparatus via a single pad and where the two sets of power supply wiring for transferring the reference voltages are connected to each other to transmit a common power supply voltage. The substates where the control circuits, scanning circuits, and current sources are disposed are not limited to the configuration described in the present embodiment, either. For example, the memory control circuit 21 and the current source 230 disposed on the second substrate 200 may be disposed on the third substrate 300. The second substrate 200 and the third substrate 300 may share the current source 330. The second substrate 200 and the third substrate 300 may be integrated into a single fourth substrate, and the photoelectric conversion apparatus 10 may be constituted by stacking the first substrate 100 and the fourth substrate.

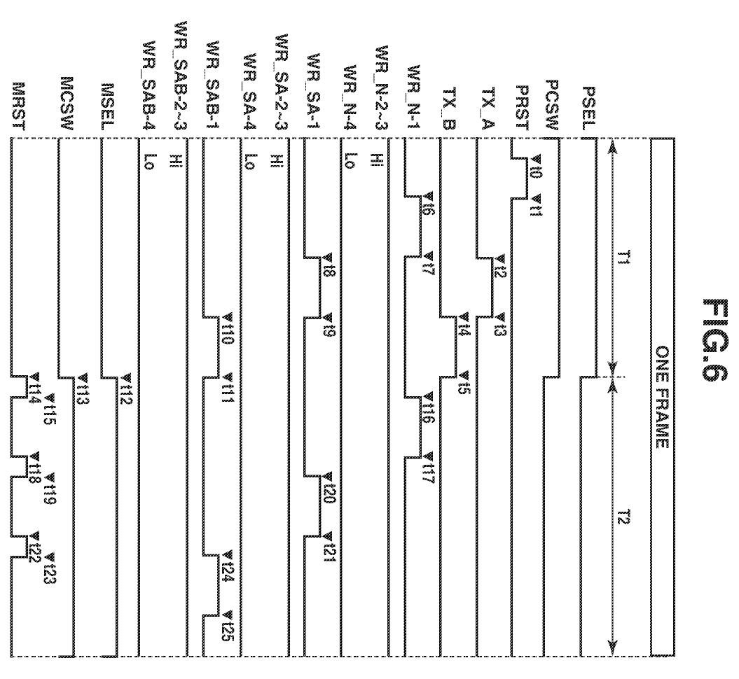

FIG. 6 is an example of a driving timing chart of the photoelectric conversion apparatus 10 according to the present embodiment. Referring to FIG. 6, period T1 where signal voltages based on the signal charges occurring in the PDs 115 and 116 are held in the signal holding memories mem and period T2 where the column signal processing circuit 50 performs AD conversion on the signal voltages held in the signal holding memories mem will be described.

In FIG. 6, the transistors shall turn on (become conducting) when the respective control signals supplied from the control circuits are high, and turn off (become non-conducting) when the respective control signals are low. In FIG. 6, the high level is denoted as Hi, and the low level as Lo. This denotation applies to the other charts as well.

The relationship between the control signals illustrated in FIG. 6 and the transistors to operate with the control signals will be described with reference to FIGS. 3 and 5. The signal charges occurring in the PDs 115 and 116 and the signal voltages held by the holding capacitor section 240 may be referred to collectively as a pixel signal.

In period T1, control signals PSEL and PCSW become high, and the selection transistor 117 and the switch transistor 217 turn on. This enables supply of the outputs from the PDs 115 and 116 to a node CH (second input node; see FIG. 3) via a source-follower (SF) circuit constituted by the amplification transistor 111 functioning as an amplification unit and the current source transistor 216. Initially, in the period from time t0 to time t1, a control signal PRST becomes high and the reset transistor 112 turns on, whereby the FD capacitor portion is reset to a potential level based on the voltage SVDD. This period will be referred to as a first reset period.

After the completion of the first reset period, in the period from time t2 to time t3, a control signal TX_A becomes high and the transfer transistor 113 turns on. As a result, the FD capacitor portion holds the signal charge generated by one photoelectric conversion element of the plurality of photoelectric conversion elements (PD 115) based on the incident light. The signal charge of the PD 115 is thereby supplied to the node CH via the SF circuit constituted by the amplification transistor 111 and the current source transistor 216. This period will be referred to as a first transfer period.

Similarly, in the period from time t4 to time t5, a control signal TX_B becomes high and the transfer transistor 114 turns on. As a result, the FD capacitor portion holds a signal charge that is the sum of the signal charges generated by one photoelectric conversion element (PD 115) and the other photoelectric conversion element (PD 116) of the plurality of photoelectric conversion elements based on the incident light. A signal corresponding to the sum of the signal charges is supplied to the node CH via the SF circuit constituted by the amplification transistor 111 and the current source transistor 216. This period will be referred to as a second transfer period. Such an operation is not restrictive, and the control signal PRST may be made high again and then made low between times t3 and t4. In such a case, when the control signal TX_B becomes high in the period from time t4 to time t5, the FD capacitor portion holds the signal charge generated by the PD 116 based on the incident light. The signal corresponding to this signal charge is supplied to the node CH via the SF circuit constituted by the amplification transistor 111 and the current source transistor 216.

Next, the control of the memory write transistors 213 to 215 and the voltage signals to be held in the signal holding memories mem will be described.

After the end of the first reset period and before the start of the first transistor period, in the period from time t6 to time t7, the potential of the FD capability portion in the reset state (hereinafter, may be referred to as an N level) is supplied to the node CH via the SF circuit constituted by the amplification transistor 111 and the current source transistor 216. This N-level signal is a signal consisting mainly of noise components. At time t6, a control signal WR_N-1 is made high to turn the memory write transistor 213-1 on, whereby the N level is sampled into the signal holding memory Nmem. At time t7, the control signal WR_N-1 is made low to hold the N level. In the example of FIG. 6, control signals WR_N-2 and WR_N-3 are kept high and a control signal WR_N-4 is kept low, so that the N level is held in the signal holding memories Nmem1 and Nmem2. In other words, in the period where the signal holding memories Nmem1 and Nmem2 are selected, the signal holding memory Nmem3 is deselected.

Here, a fixed potential is supplied to the not-selected signal holding memory Nmem3. The selection of the signal holding memories Nmem1 to Nmem3 can be switched by switching the control of the control signals WR_N-2 to WR_N-4. In other words, the capacitance of the signal holding memory Nmem can be adjusted to change the capacitance of the holding capacitor section 240.

The period from time t8 to time t9 is a first transfer period, where the potential based on the signal charge of the PD 115 (hereinafter, may be referred to as an SA level) at the FD capacitor portion is supplied to the node CH via the SF circuit constituted by the amplification transistor 111 and the current source transistor 216. At time t8, a control signal WR_SA-1 is made high to turn the memory write transistor 214-1 on, whereby the SA level is sampled into the signal holding memory Smem-A. At time t9, the control signal WR_SA-1 is made low to hold the SA level. In the example of FIG. 6, control signals WR_SA-2 and WR_SA-3 are kept high and a control signal WR_SA-4 is kept low, so that the SA level is held in the signal holding memories Smem-A1 and Smem-A2. The selection of the signal holding memories Smem-A1 to Smem-A3 can be switched by switching the control of the control signals WR_SA-2 to WR_SA-4. In other words, the capacitance of the signal holding memory Smem-A can be adjusted to change the capacitance of the holding capacitor section 240.

Similarly, the period from time t10 to time t11 is a second transfer period, where the potential based on the signal charges of the PDs 115 and 116 (hereinafter, may be referred to as an SAB level) at the FD capacitor portion is connected to the node CH via the SF circuit constituted by the amplification transistor 111 and the current source transistor 216. At time t10, a control signal WR_SAB-1 is made high to turn the memory write transistor 215-1 on, whereby the SAB level is sampled into the signal holding memory Smem-AB. Then, at time t11, the control signal WR_SAB-1 is made low to hold the SAB level. In the example of FIG. 6, control signals WR_SAB-2 and WR_SAB-3 are kept high and a control signal WR_SAB-4 is kept low, so that the SAB level is held in the signal holding memories Smem-AB1 and Smem-AB2. The selection of the signal holding memories Smem-AB1 to Smem-AB3 can be switched by switching the control of the control signals WR_SAB-2 to WR_SAB-4. In other words, the capacitance of the signal holding memory Smem-AB can be adjusted to change the capacitance of the holding capacitor section 240. The capacitances of the respective signal holding memories are desirably changed based on a possible range of signal amplitude of the signals output from the pixel 30.

Through such operations, the N level, the SA level, and the SAB level are held in the signal holding memories mem as signal voltages. The period where the signal holding memories mem sample and hold the signal voltages will be referred to as a voltage holding operation period.

The series of operations from the start of the first reset period to the end of the second transfer period will be referred to as a pixel signal voltage holding operation. The global electronic shutter operation can be implemented by simultaneously performing the pixel signal voltage holding operation on all the pixels 30. The pixel signal voltage holding operation may be performed on all the pixels of the plurality of pixels 30 and all the pixel memories of the plurality of pixel memories 40, or on some of the pixels 30 of the plurality of pixels and some of the pixel memories 40 of the plurality of pixel memories. For example, the pixel signal voltage holding operation may be sequentially performed in units of a plurality of pixel rows or a plurality of pixel columns. The pixel signal voltage holding operation may be performed row by row.

After the pixel signal voltage holding operation, the signal voltages held in the signal holding memories mem are read out into the column signal processing circuit 50.

In period T2 illustrated in FIG. 6, the selection transistor 117 turns off. The pixel 30 and the pixel memory 40 are thereby disconnected. Moreover, the switch transistor 217 turns off, whereby the current supplied from the current source transistor 216 is interrupted, and the SF circuit constituted by the amplification transistor 111 and the current source transistor 216 becomes inoperative. This makes the node CH floating. After time t11, a control signal MSEL becomes high at time t12, whereby the selection transistor 218 is turned on. At time t13, a control signal MCSW becomes high to turn the switch transistor 314 on. This establishes connection to the ADC 311 via an SF circuit constituted by the amplification transistor 211 and the current source transistor 313, which functions as an amplification unit for amplifying the signals read from the signal holding memories mem. Time t12 and time t13 may be the same timing.

In the period from time t14 to time t15, a control signal MRST becomes high and the reset transistor 212 turns on, whereby the node CH is reset to a potential level based on the voltage MVDD. This period will be referred to as a second reset period.

After the second reset period, in the period from time t16 to time t17, the control signal WR_N-1 is made high to turn the memory write transistor 213-1 on, whereby the signal voltage held in the signal holding memories Nmem1 and Nmem2 is output to the node CH. The ADC 311 performs AD conversion on the signal voltage held in the signal holding memories Nmem1 and Nmem2, read out via the SF circuit constituted by the amplification transistor 211 and the current source transistor 313, i.e., the voltage based on the N level. This period will be referred to as a first AD conversion period.

The potential of the node Ch is determined by the capacitance of the node CH, the diffusion capacitances of the wiring and the memory write transistors 213-1, 214-1, and 215-1, the capacitance of the gate electrode of the amplification transistor 211, the ratios between the capacitance of the gate electrode of the amplification transistor 211 and the capacitances of the signal holding memories, and potential differences between the nodes. In the operation illustrated in FIG. 6, the second reset period for turning on and then turning off the reset transistor 212 is therefore provided to reset the node CH to a constant potential before the voltage held in each signal holding memory mem is read out.

A second reset period for turning on and then turning off the reset transistor 212 is provided after the first AD conversion period, between times t18 and t19.

After the second reset period from time t18 to time t19, in the period from time t20 to time t21, the control signal WR_SA-1 is made high to turn the memory write transistor 214-1 on. The signal voltage held in the signal holding memories Smem-A1 and Smem-A2 is thereby output to the node CH. The ADC 311 performs AD conversion on the signal voltage held in the signal holding memories Smem-A1 and Smem-A2, read out via the SF circuit constituted by the amplification transistor 211 and the current source transistor 313, i.e., the voltage based on the SA level. This period will be referred to as a second AD conversion period.

A second reset period for turning on and then turning off the reset transistor 212 is provided after the second AD conversion period, between times t22 and t23.

After the second reset period from time t22 to time t23, in the period from time t24 to time t25, the control signal WR_SAB-1 is made high to turn the memory write transistor 215-1 on. The signal voltage held in the signal holding memory Smem-AB1 and Smem-AB2 is thereby output to the node CH. The ADC 311 performs AD conversion on the voltage signal held in the signal holding memories Smem-AB1 and Smem-AB2, read out via the SF circuit constituted by the amplification transistor 211 and the current source transistor 313, i.e., the voltage based on the SAB level. This period will be referred to as a third AD conversion period.

After the third AD conversion period, period T2 ends, and the selection transistor 218 and the switch transistor 314 turn off. The pixel memory 40 and the column signal processing circuit 50 are thereby disconnected. With the switch transistor 314 turned off, the current supplied from the current source transistor 313 is interrupted, and the SF circuit including the amplification transistor 211 and the current source transistor 313 becomes inoperative.

In the operation illustrated in FIG. 6, the reset operations of the PDs 115 and 116 are not explicitly described. For example, the first transfer period and the second transfer period may be followed by respective accumulation start times. Alternatively, in period T2 or at timing other than periods T1 and T2, the transfer transistor 113, the transfer transistor 114, and the reset transistor 112 may be turned on. The PDs 115 and 116 are thereby reset to a potential based on the voltage SVDD. Reset transistors other than the reset transistor 112 may be disposed between the PDs 115 and 116 and the voltage SVDD, and reset operations may be performed using the reset transistors.

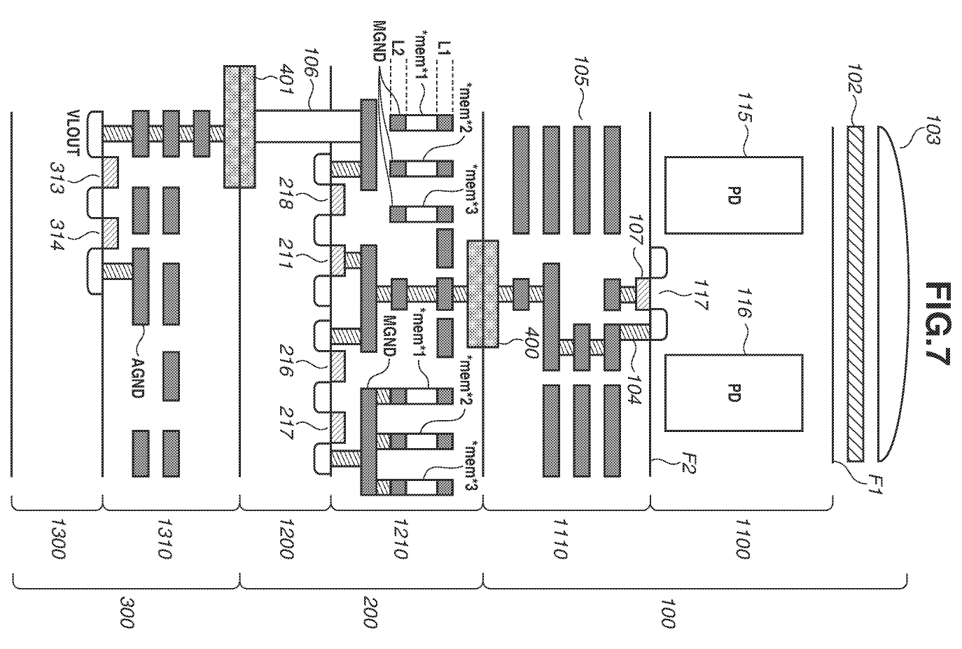

FIG. 7 illustrates a cross-sectional structure of the first, second, and third substrates 100, 200, and 300 according to the present embodiment, including metal bonding portions. FIG. 7 illustrates some of the elements and wiring connections included in the configuration described with reference to FIG. 3.

The first substrate 100 includes a semiconductor substrate 1100 (first semiconductor layer) and a wiring structure 1110 (first wiring structure). The semiconductor substrate 1100 is a silicon semiconductor substrate, for example, and is a first semiconductor layer where the photoelectric conversion elements and reading circuits for reading out signals based on the photoelectric conversion of the photoelectric conversion elements are formed. If the photoelectric conversion elements are not PDs but a photoelectric conversion film, the photoelectric conversion film may be disposed on top of the first semiconductor layer. The semiconductor substrate 1100 may be made of materials other than silicon. For example, the semiconductor substrate 1100 may be a compound semiconductor substrate such as a gallium arsenide substrate. In the following description, the semiconductor substrate 1100 is assumed to be a silicon monocrystalline substrate.

FIG. 7 illustrates the PDs 115 and 116 and the selection transistor 117 as examples of the elements disposed in the semiconductor substrate 1100. A microlens 103 and a color filter 102 are formed on the light incident surface of the semiconductor substrate 1100. The color filter 102 has a function of limiting the wavelength band of the incident light. For example, the color filter 102 can transmit light in respective wavelength bands corresponding to red, green, and blue of visible light.

The microlens 103 has a function of focusing the incident light on the PDs 115 and 116. A first main surface F1 of the semiconductor substrate 1100 is the surface on which the incident light is incident. A main surface F2 of the semiconductor substrate 1100 is the surface where the gates of the transistors are disposed. The second main surface F2 is located between the first main surface F1 and the wiring structure 1110 (first wiring structure) of the first substrate 100.

The wiring structure 1110 includes multiple layers of metal wiring 150 for connecting circuits. Contact vias 104 for connecting components are disposed between the layers of metal wiring 105, between the metal wiring 105 and the semiconductor substrate 1100, and between the metal wiring 105 and the transistors formed in the semiconductor substrate 1100. For example, a contact via 104 is connected to the source region of the selection transistor 117.

A gate electrode 107 is polysilicon constituting the gate electrode of the selection transistor 117. The wiring structure 1110 is the first wiring structure that electrically connects the PDs 115 and 116, the reading circuits included in the semiconductor substrate 1100, and reading circuits included in the second substrate 200.

The second substrate 200 includes a semiconductor substrate 1200 and a wiring structure 1210 (second wiring structure) of the second substrate 200. The semiconductor substrate 1200 is a silicon semiconductor substrate, for example, and is a second semiconductor layer including the signal holding memories and output circuits for outputting the voltages held in the signal holding memories. The semiconductor substrate 1200 may be made of materials other than silicon. For example, the semiconductor substrate 1200 may be a compound semiconductor substrate such as a gallium arsenide substrate. In the following description, the semiconductor substrate 1200 is assumed to be a silicon monocrystalline substrate. As illustrated in FIG. 7, the semiconductor substrates 1100 and 1200 may have different thicknesses or the same thickness. If the thicknesses are different, for example, the semiconductor substrate 1100 may have a thickness smaller than that of the semiconductor substrate 1200.

FIG. 7 illustrates the current source transistor 216, the switch transistor 217, the amplification transistor 211, and the selection transistor 218 as examples of the elements disposed in the semiconductor substrate 1200.

Like the wiring structure 1110 of the first substrate 100, the wiring structure 1210 of the second substrate 200 is a wiring structure formed by metal wiring 105, contact vias 104, and gate electrodes 107.

The signal holding memories Nmem1 to Nmem3, the signal holding memories Smem-A1 to Smem-A3, and the signal holding memories Smem-AB1 to Smem-AB3 described with reference to FIGS. 3 and 5 are formed in the wiring structure 1210.

In FIG. 7, the signal holding memories are denoted by *mem*1 to *mem*3 and illustrated as a plurality of signal holding memories with respective separate electrodes. The wiring structure 1210 electrically connects the signal holding memories mem to the respective output circuits. Here, the signal holding memories mem may be any components as long as they have a function of holding a signal voltage, and may be configured so that signals are held in capacitors formed in the semiconductor substrate 1200 as described above. This configuration will be described below.

The third substrate 300 includes a semiconductor substrate 1300 and a wiring structure 1310 (third wiring structure). The semiconductor substrate 1300 is a silicon semiconductor substrate, for example, and is a third semiconductor layer including second reading circuits for reading out signals based on the voltages held in the signal holding memories. FIG. 7 illustrates the current source transistor 313 and the switch transistor 314 as examples of the elements disposed in the semiconductor substrate 1300.

The wiring structure 1310 is a third wiring structure that is formed by metal wiring 105, contact vias 104, and gate electrodes 107 like the wiring structure 1110, and electrically connected to the second reading circuits.

As illustrated in FIG. 7, the first substrate 100 and the second substrate 200 are laminated with the wiring structure 1110 and the wiring structure 1210 opposed to each other. The metal bonding portion 400 is formed at the point of electrical connection. The metal bonding portion 400 of FIG. 7 is a CCB. The metal bonding portion 400 is formed by laminating and connecting a Cu pad (metal member) formed on the lower surface (first layer) of the wiring structure 1110 and a Cu pad (metal member) formed on the upper surface (second layer) of the wiring structure 1210. Moreover, an insulative bonding portion is formed by bonding the insulating member of the first layer and the insulating member of the second layer to each other.

The wiring structure 1210 of the second substrate 200 and the wiring structure 1310 of the third substrate 300 are connected via the semiconductor substrate 1200. A TSV 106 is formed in the semiconductor substrate 1200 and connected to a Cu pad provided on the lower surface of the semiconductor substrate 1200. This Cu pad and a Cu pad formed on the upper surface of the wiring structure 1310 are bonded to form the metal bonding portion 401 by CCB.

The selection transistor 117 is connected to the current source transistor 216 via the metal bonding portion 400. The selection transistor 218 is connected to the column signal processing circuit 50 and the current source transistor 313 via the metal bonding portion 401.

In FIG. 7, each signal holding memory mem is connected to a memory write transistor at one of its two terminals and to the reference voltage MGND at the other terminal as described with reference to FIGS. 3 and 5. In FIG. 7, a plurality of wiring traces defined by an insulating member are disposed on a third layer L1. The plurality of wiring traces on the third layer L1 includes portions (first capacitor portions) of the signal holding memories mem. The plurality of signal holding memories mem are separated from each other by the insulating member.

In FIG. 7, a plurality of wiring traces defined by the insulating member is disposed on a fourth layer L2. The plurality of wiring traces on the fourth layer L2 includes portions (second capacitor portions) of the signal holding memories mem. The plurality of signal holding memories mem are separated from each other by the insulating member. In FIG. 7, the second capacitor portions are connected to the power supply wiring of the reference voltage MGND as described with reference to FIGS. 3 and 5. However, the second capacitor portions may be connected to power supply wiring for suppling respective different voltages.

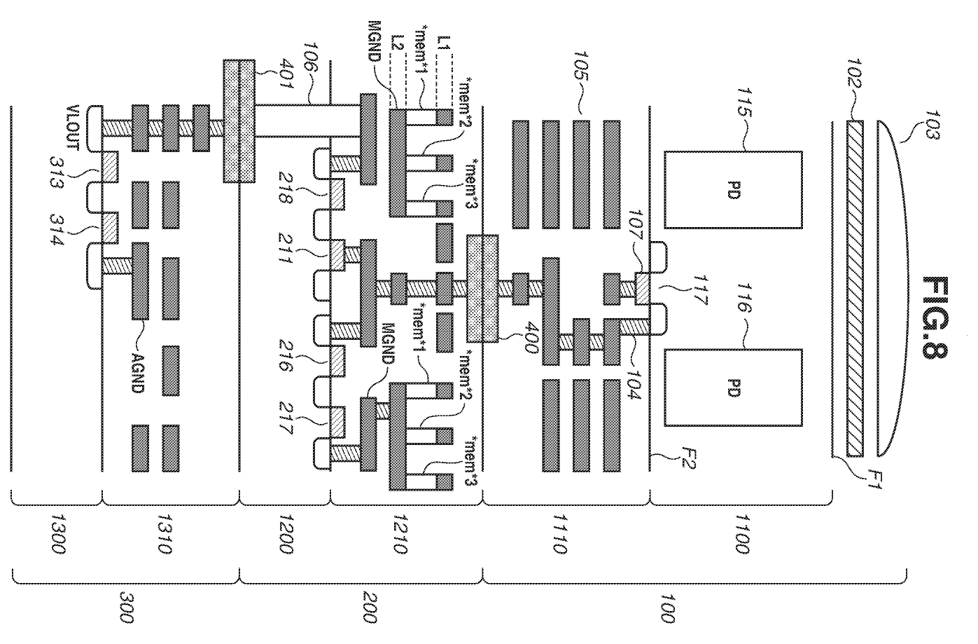

FIG. 8 is a schematic cross-sectional view of the first, second, and third substrates 100, 200, and 300 in another example than that of FIG. 7.

Like the configuration of FIG. 7, the signal holding memories Nmem1 to Nmem3, the signal holding memories Smem-A1 to Smem-A3, and the signal holding memories Smem-AB1 to Smem-AB3 are formed in the wiring structure 1210. Like FIG. 7, the signal holding memories are denoted as *mem*1 to *mem*3. FIG. 8 differs from FIG. 7 in that a plurality of signal holding memories are connected to the power supply wiring of the reference voltage MGND via a common electrode. In FIG. 8, like FIG. 7, the capacitances of the respective signal holding memories mem can be changed. By sharing the capacitor portions at the fourth layer L2 as illustrated in FIG. 8, the signal holding memories can be connected to the same power supply wiring with a low resistance. This can reduce variations in the reference voltage MGND serving as a reference for voltage holding between the signal holding memories, and can improve the quality of the held signals.

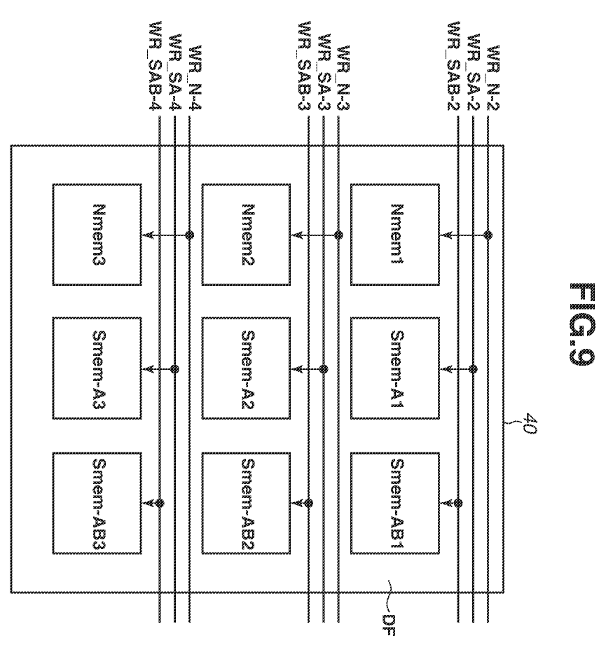

FIG. 9 is a schematic plan view of the pixel memory 40, illustrating the layout of the signal holding memories Nmem1 to Nmem3, the signal holding memories Smem-A1 to Smem-A3, and the signal holding memories Smem-AB1 to Smem-AB3 disposed in the wiring structure 1210. FIG. 9 illustrates the third layer L1 illustrated FIG. 7 in a plan view with respect to the semiconductor substrate 1100. FIG. 9 can be said to illustrate a plurality of wiring traces on the third layer L1.

The arrows represent the connections between the signal holding memories and the control signals, including the memory write transistors. The signal holding memories are controlled by the respective control signals. "Control" here refers to control of either selection or deselection of the signal holding memories, for example. The control signals WR_N-1, WR_SA-1, and WR_SAB-1 for controlling the memory write transistors 213-1, 214-1, and 215-1 are omitted.

The plurality of wiring traces on the third layer L1 are electrically isolated by an insulating member DF. A schematic plan view of the fourth layer L2 may be similar to FIG. 9. In FIG. 9, the signal holding memories Nmem1 to Nmem3 are vertically arranged, the signal holding memories Smem-A1 to Smem-A3 are vertically arranged, and the signal holding memories Smem-AB1 to Smem-AB3 are vertically arranged. The control signal lines of the control signals WR_N-2, WR_SA-2, and WR_SAB-2 are arranged next to each other. Similarly, the control signal lines of the control signals WR_N-3, WR_SA-3, and WR_SAB-3 are arranged next to each other, and the control signal lines of the control signals WR_N-4, WR_SA-4, and WR_SAB-4 are arranged next to each other. However, this layout example is not restrictive.

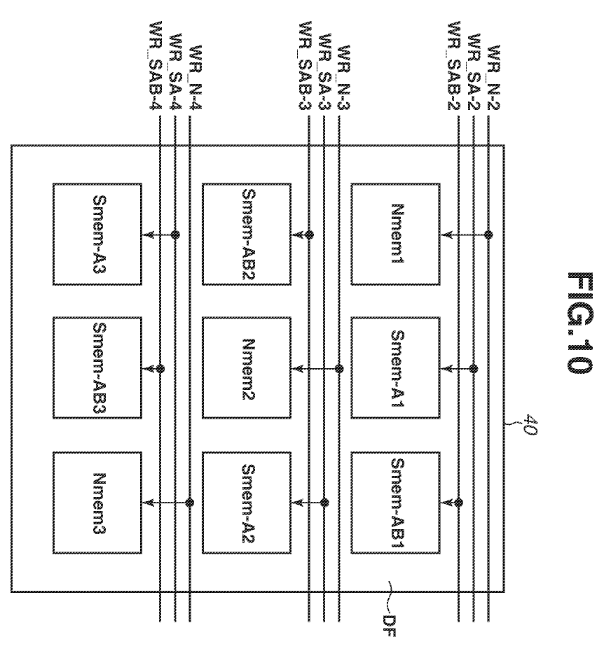

FIG. 10 is a schematic plan view of the pixel memory 40, illustrating the layout of the signal holding memories Nmem1 to Nmem3, the signal holding memories Smem-A1 to Smem-A3, and the signal holding memories Smem-AB1 to Smem-AB3 in another example than that of FIG. 9. The signal holding memories Nmem1 to Nmem3, the signal holding memories Smem-A1 to Smem-A3, and the signal holding memories Smem-AB1 to Smem-AB3 may be arranged in respective irregular patterns. FIG. 10 differs from FIG. 9 in that the signal holding memories Nmem1 to Nmem3 are diagonally arranged. Similarly, the signal holding memories Smem-A1 to Smem-A3 and the signal holding memories Smem-AB1 to Smem-AB3 are also diagonally arranged. The control signal lines are arranged as in FIG. 9.

As the operation timing is described with reference to FIG. 6, the signal holding memories Nmem, the signal holding memories Smem-A, and the signal holding memories Smem-AB hold the N level, the SA level, and the SAB level of the voltage signal through sample-and-hold operations. For example, the period from time t6 to time t7 where the N level is sampled into the signal holding memory Nmem (sampling period N) is substantially determined by the driving power of the SF circuit constituted by the amplification transistor 111 and the current source transistor 216 and the capacitance of the signal holding memory Nmem. The driving power of the SF circuit refers to, for example, the amount of current for the current source transistor 216 to pass. The amount of current for the current source transistor 216 to pass can be made variable by adjusting the size of the bias generation transistor 231 described with reference to FIG. 4 to adjust the current mirror ratio. The amount of current for the current source transistor 216 to pass can also be made variable by adjusting the current of the reference current source 232. Furthermore, the amount of current for the current source transistor 216 to pass can be made variable by changing the voltage applied to the gate of the current source transistor 216. A similar configuration applies to the period from time t8 to time t9 where the SA level is sampled into the signal holding memories Smem-A1 and Smem-A2 (sampling period SA). A similar configuration also applies to the period from time t10 to time t11 where the SAB level is sampled into the signal holding memories Smem-AB1 and Smem-AB2 (sampling period SAB).

As described with reference to FIG. 6, one frame period is determined by periods T1 and T2. In other words, to increase the frame rate of the photoelectric conversion apparatus 10, at least one of periods T1 and T2 is to be reduced. Period T1 is substantially determined by the sampling period N, the sampling period SA, and the sampling period SAB. For example, to reduce period T1, the driving power of the SF circuit constituted by the amplification transistor 111 and the current source transistor 216 is to be increased. For example, the current to pass through the current source transistor 216 is to be increased. This involves increasing the current through each pixel, and power consumption may increase. Alternatively, period T1 can be reduced by reducing the capacitances of the signal holding memories mem to shorten the sampling periods. Reducing the capacitances of the signal holding memories mem, however, changes the frequency band of noise. This can degrade noise performance, lower the precision of the capacitances, and increase variations in the capacitances, thereby causing degradation in image quality and imaging performance such as a drop in the precision of the held voltages and phase difference detection. Period T2 can be adjusted by changing the driving power of the SF circuit constituted by the amplification transistor 211 and the current source transistor 313 depending on the capacitances of the signal holding memories mem, but power consumption can increase as well. The number of column signal processing circuits 50 can be increased to increase the number of parallel signal processes for speedup, in which case the area and power consumption may increase.

In the present embodiment, the capacitances of the signal holding memories mem, the driving power of the amplification transistor 111, and the driving power of the amplification transistor 211 can be set as appropriate. In the photoelectric conversion apparatus 10 having the voltage holding global electronic shutter function, the capacitances and the driving power of the SF circuits can thus be set in consideration of the sizes of the capacitive elements and signal settling times, whereby the imaging performance may be able to be further improved.

From another perspective, when the sampling period N, the sampling period SA, and the sampling period SAB are long, the photoelectric conversion apparatus 10 becomes susceptible to low frequency noise, for example. Increased holding periods of the capacitors can contribute to image quality degradation, including lower precision of the held voltages due to leak currents from the signal holding memories. In other words, longer period T1 can be said to significantly affect the image quality performance. The degrees of impact also vary depending on the capacitances of the signal holding memories.

In the present embodiment, as described with reference to FIGS. 5 and 6, the signal holding memory Nmem, the signal holding memory Smem-A, and the signal holding memory Smem-AB are configured so that their capacitances can be selected using the control signals WR_N-2 to WR_N-4, WR_SA-2 to WR_SA-4, and WR_SAB-2 to WR_SAB-4. For example, to acquire a high-quality image with low readout speed, such as in one-shot still image capturing, the signal holding memories Nmem1 to Nmem3, the signal holding memories Smem-A1 to Smem-A3, and the signal holding memories Smem-AB1 to Smem-AB3 are all selected. This reduces noise and the impact of leakage. Reducing the driving power of the SF circuit constituted by the amplification transistor 111 and the current source transistor 216 enables a configuration that suppresses an increase in power consumption, but with an increase in period T1. In situations where a moving image is captured at a high frame rate and image quality degradation can be tolerated, the signal holding memory Nmem1, the signal holding mem Smem-A1, and the signal holding memory Smem-AB1 are selected, allowing an increase in noise and the impact of leakage. By contrast, increasing the driving power of the SF circuit constituted by the amplification transistor 111 and the current source transistor 216 enables a configuration that shortens period T1, but with an increase in power consumption. In such a case, in the layout illustrated in FIG. 9, signal holding memories that are not physically juxtaposed, like the signal holding memories Nmem1, Smem-A2, and Smem-AB3, may be selected. Such a configuration can reduce crosstalk between the signal holding memories.

The current source transistor 216 may have a gate width different from that of the current source transistor 313. For example, the gate width of the current source transistor 216 may be greater than that of the current source transistor 313. This can increase the driving power of the first amplification unit, compared to that of the second amplification unit.

According to the photoelectric conversion apparatus 10 of the present embodiment, the numbers of signal holding memories to be selected, i.e., the capacitances can be selected and made variable. For example, the capacitance of the holding capacitor section 240 can be changed depending on a change in the on-periods of the memory write transistors. Moreover, the driving power of the SF circuit constituted by the amplification transistor 111 and the current source transistor 216 can be adjusted. Similarly, the driving power of the SF circuit constituted by the amplification transistor 211 and the current source transistor 313 can be adjusted. The capacitance of the holding capacitor section 240 can be changed based on a change in the driving power of at least either the amplification transistor 111 or the amplification transistor 211. In such a manner, the capacitances can be appropriately selected and adjusted based on desired image quality performance and imaging performance.

Depending on the capacitances of the signal holding memories mem, the operation of the reset transistor 212 may be adjusted. The reset transistor 212 may be configured to be adjustable in size. The size here may be the gate width of the gate electrode or the gate length of the gate element, for example. If the signal holding memories mem are configured to be reset using the reset transistor 212, the reset period is adjusted or the size of the reset transistor 212 is switched depending on the capacitances of the signal holding memories mem. For example, if the capacitances of the signal holding memories mem are large, the reset period is increased or the size of the reset transistor 212 is increased. This can improve the resetting precision of the signal holding memories mem.

From another perspective, if a defect (characteristic defect or failure) is found in any of the signal holding memories Nmem1 to Nmem3, Smem-A1 to Smem-A3, and Smem-AB1 to Smem-AB3, that memory may be disused. For example, in the schematic plan view of the pixel memory 40 illustrated in FIG. 9, suppose that a defect is found in the signal holding memory Smem-A2 of the pixel memory 40. In such a case, the signal holding memory Smem-A2 of the pixel memory 40 may be disused. With such a configuration, if any of the signal holding memories is defective, degradation in image quality may be able to be reduced through the control of disusing the signal holding memory. As another configuration, backup signal holding memories may be provided, and if a signal holding memory is found to be defective, the connection is switched to a backup signal holding memory for use.

The layout, spacing, shape, and size of the signal holding memories mem are not limited to the configuration described in the present embodiment. For example, as has been described in part in the present embodiment, the signal holding memories mem may have the same size or different sizes. The signal holding memories mem may have the same shape or different shapes. The signal holding memories mem may be arranged at different spacings.

As has been described above, according to the present embodiment, the image quality performance and the imaging performance can be optimally set by constituting the signal holding memories for holding the pixel signals generated by the photoelectric conversion elements with a plurality of capacitive elements and controlling the capacitive elements.

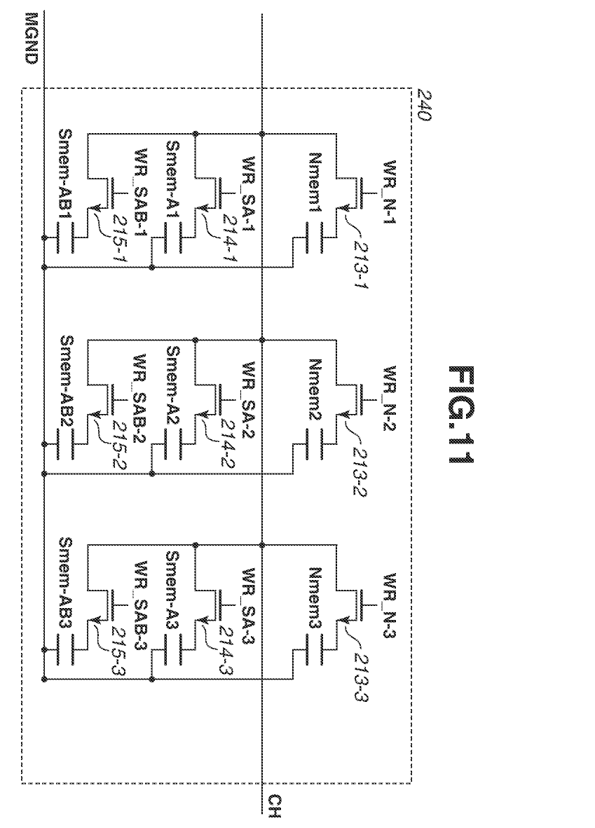

A photoelectric conversion apparatus according to a second embodiment of the present invention will be described with reference to FIGS. 11 to 13.

FIG. 11 is a circuit diagram of signal holding memories (holding capacitor section 240) in the photoelectric conversion apparatus according to the second embodiment. Memory write transistors and the signal holding memories are denoted by the same reference numerals as in FIG. 5, but there are differences from the first embodiment in the configuration and connection of FIG. 5. Except for this respect and what is described below, the configuration of the second embodiment can be substantially the same as that of the first embodiment. A description thereof may therefore be omitted.

A signal holding memory Nmem includes a plurality of signal holding memories Nmem1 to Nmem3. A memory write transistor 213 includes memory write transistors 213-1 to 213-3. The drains of the memory write transistors 213-1 to 213-3 are connected to the gate of an amplification transistor 211. The plurality of signal holding memories Nmem1 to Nmem3 are connected to power supply wiring for supplying a reference voltage MGND at one of their terminals each. The other terminals are connected to the sources of the memory write transistors 213-1 to 213-3, respectively. Similarly, a signal holding memory Smem-A includes a plurality of signal holding memories Smem-A1 to Smem-A3. A memory write transistor 214 includes memory write transistors 214-1 to 214-3. The drains of the memory write transistors 214-1 to 214-3 are connected to the gate of the amplification transistor 211. The plurality of signal holding memories Smem-A1 to Smem-A3 are connected to the power supply wiring for supplying the reference voltage MGND at one of their terminals each. The other terminals are connected to the sources of the memory write transistors 214-1 to 214-3, respectively. A signal holding memory Smem-AB includes a plurality of signal holding memories Smem-AB1 to Smem-AB3. A memory write transistor 215 includes memory write transistors 215-1 to 215-3. The drains of the memory write transistors 215-1 to 215-3 are connected to the gate of the amplification transistor 211. The plurality of signal holding memories Smem-AB1 to Smem-AB3 are connected to the power supply wiring for supplying the reference voltage MGND at one of their terminals each. The other terminals are connected to the sources of the memory write transistors 215-1 to 215-3, respectively.

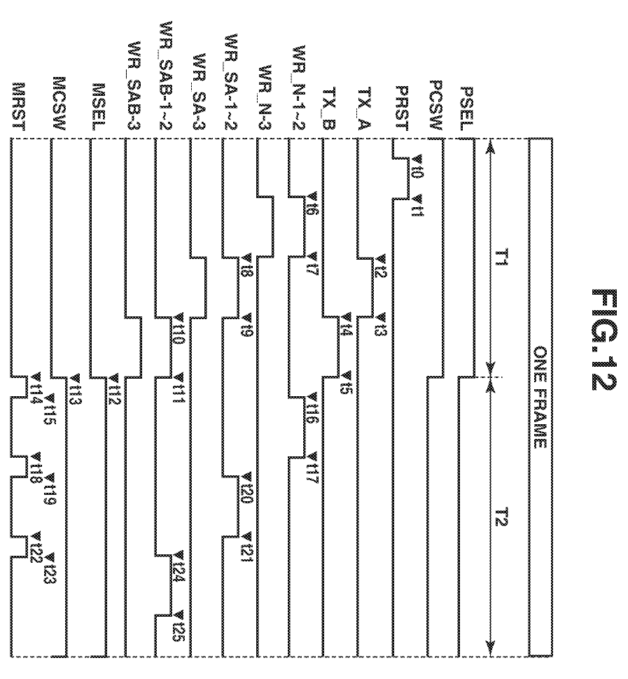

FIG. 12 is an example of a driving timing chart of the photoelectric conversion apparatus according to the present embodiment. More specifically, FIG. 12 is a chart for describing the driving timing of the reading circuit of FIGS. 3 and 11. A description of operations redundant with those described with reference to FIG. 6 will be omitted.

In the operation timing of FIG. 12, in the sampling period N from time t6 to time t7, the control signals WR_N-1 to WR_N-3 are made high to hold the N level in the signal holding memories Nmem1 to Nmem3. By contrast, in period T2, the control signals WR_N-1 and WR_N-2 are made high to read out the signal voltage held in the signal holding memories Nmem1 and Nmem2.

Similarly, in the sampling period SA from time t8 to time t9, the control signals WR_SA-1 to WR_SA-3 are made high to hold the SA level in the signal holding memories Smem-A1 to Smem-A3. By contrast, in period T2, the control signals WR_SA-1 and WR_SA-2 are made high to read out the signal voltage held in the signal holding memories Smem-A1 and Smem-A2. In the sampling period SAB from time t10 to time t11, the control signals WR_SAB-1 to WR_SAB-3 are made high to hold the SAB level in the signal holding memories Smem-AB1 to Smem-AB3. By contrast, in period T2, the control signals WR_SAB-1 and WR_SAB-2 are made high to read out the signal voltage held in the signal holding memories Smem-AB1 and Smem-AB2. In such a manner, the capacitance of the holding capacitor section 240 is changed depending on the reading mode.

In the present embodiment, in reading the output of the SF circuit constituted by the amplification transistor 111 and the current source transistor 216 in period T1, the signal holding memory to serve as the load capacitor of the SF circuit output is increased in capacitance. The capacitance of the signal holding memory (holding capacitor section 240) can thus be changed depending on the gain processing. High frequency components of noise from the SF circuit can thereby be reduced. By contact, in reading out the signal voltages held in the signal holding memories in period T2, the numbers of signal holding memories are reduced from in period T1. This can reduce the impact of switching noise that can occur in holding the signal voltages in period T1 and switching noise that can occur during selection in period T2.

Even in the configuration of FIG. 5, for example, the control signals WR_SA-2 to WR_SA-4 can be made high to select the signal holding memories Smem-A1 to Smem-A3 in period T1, and the control signal WR_SA-4 can be made low to select and read the signal holding memories Smem-A1 and Smem-A2 in period T2. This, however, leads to superposition of switching noise due to the switching of the control signal WR_SA-4 from high to low between periods T1 and T2, and can thus degrade the image quality. The configuration illustrated in FIG. 11 is therefore desirable. When the signal holding memories are read out in period T2 as described with reference to FIG. 6, the potential of the node CH varies with the capacitances of the signal holding memories. The signal holding memories may therefore be selected for the purpose of adjusting the potential of the node CH.

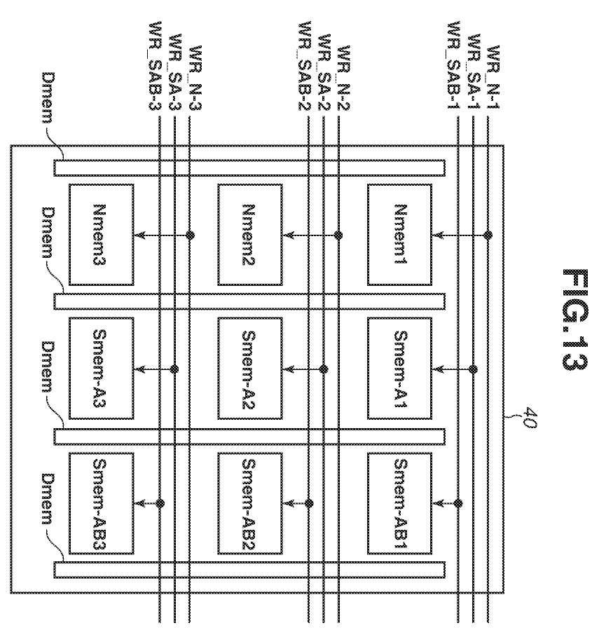

FIG. 13 is an example of a schematic plan view of the holding capacitor section 240 of FIG. 11. In FIG. 13, capacitive elements Dmem not illustrated in FIG. 11 are disposed between the signal holding memories Nmem and Smem-A, between the signal holding memories Smem-A and Smem-AB, and between pixel memories 40.

As described with reference to FIGS. 3 and 6, the signal holding memories Nmem, Smem-A, and Smem-AB are subjected to the holding operations of the N level, SA level, and SAB level of the voltage signals and the reading operations of the same at respective different times. For example, if there is parasitic capacitance between the signal holding memories mem, the voltage signals held in the respective signal holding memories mem vary due to crosstalk. Suppose, for example, that the signal holding memory Nmem has a capacitance of CN, the signal holding memory Smem-A a capacitance of CA, and the signal holding memory Smem-AB a capacitance of CAB, and there is parasitic capacitance Cp between the signal holding memories. If, as described with reference to FIG. 6, the voltage on the signal holding memory Smem-AB varies by ΔV in the period from time t10 to time t11, the signal holding memory Nmem undergoes a voltage variation given by Exp. (1), and the signal holding memory Smem-A a voltage variation given by Exp. (2): ΔV × Cp/(Cp + CN), and ... (1) ΔV × Cp/(Cp + CA). ... (2)

In reading out the voltage signals of the signal holding memories mem into the column signal processing circuit 50 in period T2, the voltages on the signal holding memories mem also vary depending on the reset level of the node CH. As a result, crosstalk occurs due to the parasitic capacitance Cp between the signal holding memories mem. Similarly, if there is parasitic capacitance between the pixel memories 40, crosstalk also occurs between the pixel memories 40. Such crosstalk can be error factors for the signal charges generated by the PDs 115 and 116. For example, a linearity error and an offset error with respect to the incident light can occur in the pixel output signals. Crosstalk between the signal holding memories Smem-A and Smem-AB can result in a phase difference detection error. Crosstalk between pixels 40 leads to mixing of colors between different color pixels and degrades the image quality.

In the present embodiment, like the first embodiment, the capacitances and the driving power of the SF circuits can be appropriately selected and adjusted based on the desired image quality performance and imaging performance. Moreover, the provision of the dummy capacitive elements Dmem as illustrated in FIG. 13 can reduce crosstalk between the signal holding memories.

The capacitive elements Dmem may be connected to the power supply wiring of a power supply voltage VDD, a reference voltage GND, or other reference voltages. The capacitive elements Dmem may be connected to write transistors and configured to be usable as signal holding memories.

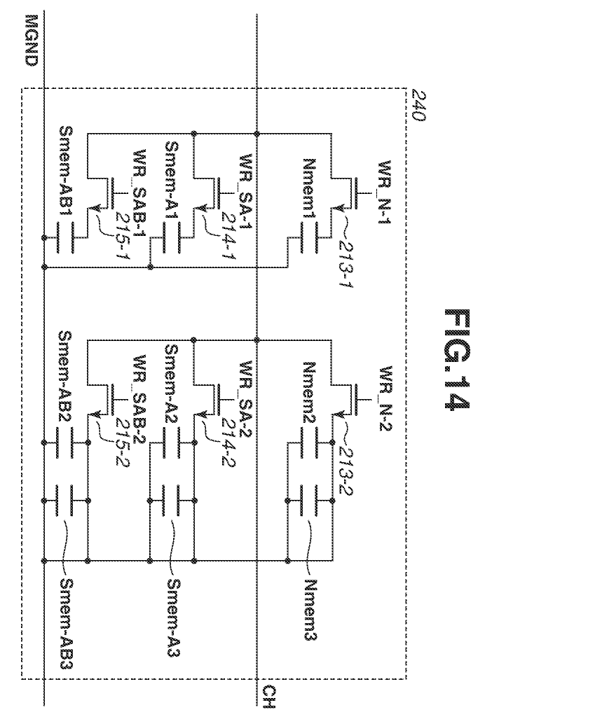

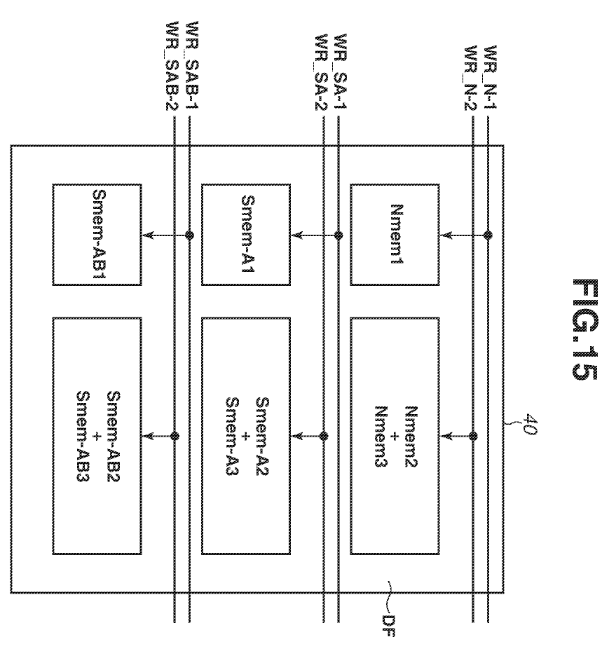

A photoelectric conversion apparatus according to a third embodiment of the present invention will be described with reference to FIGS. 14 and 15.

FIG. 14 is a circuit diagram of signal holding memories (holding capacitor section 240) in the photoelectric conversion apparatus according to the third embodiment. Memory write transistors and the signal holding memories are denoted by the same reference numerals as in FIG. 5, but the number and connection of memory write transistors are different from the first and second embodiments. Except for this respect and what is described in the following, the configuration can be substantially the same as that of the first embodiment. A description thereof may therefore be omitted.

A signal holding memory Nmem includes a plurality of signal holding memories Nmem1 to Nmem3. A memory write transistor 213 includes memory write transistors 213-1 and 213-2. The drains of the memory write transistors 213-1 and 213-2 are connected to the gate of an amplification transistor 211. The plurality of signal holding memories Nmem1 to Nmem3 are connected to power supply wiring for supplying a reference voltage MGND at one of their terminals each. The other terminal of the signal holding memory Nmem1 is connected to the source of the memory write transistor 213-1. The other terminals of the signal holding memories Nmem2 and Nmem3 are connected to the source of the memory write transistor 213-2.

A signal holding memory Smem-A includes a plurality of signal holding memories Smem-A1 to Smem-A3. A memory write transistor 214 includes memory write transistors 214-1 and 214-2. The drains of the memory write transistors 214-1 and 214-2 are connected to the gate of the amplification transistor 211. The plurality of signal holding memories Smem-A1 to Smem-A3 are connected to the power supply wiring for supplying the reference voltage MGND at one of their terminals each. The other terminal of the signal holding memory Smem-A1 is connected to the source of the memory write transistor 214-1. The other terminals of the signal holding memories Smem-A2 and Smem-A3 are connected to the source of the memory write transistor 214-2.

A signal holding memory Smem-AB includes a plurality of signal holding memories Smem-AB1 to Smem-AB3. A memory write transistor 215 includes memory write transistors 215-1 and 215-2. The drains of the memory write transistors 215-1 and 215-2 are connected to the gate of the amplification transistor 211. The plurality of signal holding memories Smem-AB1 to Smem-AB3 are connected to the power supply wiring for supplying the reference voltage MGND at one of their terminals each. The other terminal of the signal holding memory Smem-AB1 is connected to the source of the memory write transistor 215-1. The other terminals of the signal holding memories Smem-AB2 and Smem-AB3 are connected to the source of the memory write transistor 215-2.

In the present embodiment, the signal holding memories mem selected by the write transistors 213-1, 214-1, and 215-1 and the signal holding memories mem selected by the write transistors 213-2, 214-2, and 215-2 have explicitly different capacitances. In FIG. 14, the signal holding memories Nmem2 and Nmem3, the signal holding memories Smem-A2 and Smem-A3, and the signal holding memories Smem-AB2 and Smem-AB3 are connected in parallel to produce the differences in capacitance. Each pair of signal holding memories may be replaced with a signal holding memory having the different capacitance.

Even in the present embodiment, the capacitors of different sizes may be configured to be selectable depending on the image quality performance and imaging performance as described with reference to FIG. 6. As described with reference to FIG. 12, the control of the memory write transistors may be switched between periods T1 and T2.

FIG. 15 is a plan view illustrating the configuration of the pixel memory 40 of FIG. 14. In the circuit diagram of FIG. 14, the signal holding memories Nmem2 and Nmem3, the signal holding memories Smem-A2 and Smem-A3, and the signal holding memories Smem-AB2 and Smem-AB3 are arranged in parallel. Since each pair of signal holding memories is handled substantially as one signal holding memory, FIG. 15 illustrates each pair as one signal holding memory.

Even in the present embodiment, like the first embodiment, the capacitances and the driving power of the SF circuits can be appropriately selected and adjusted based on the desired image quality performance and imaging performance.

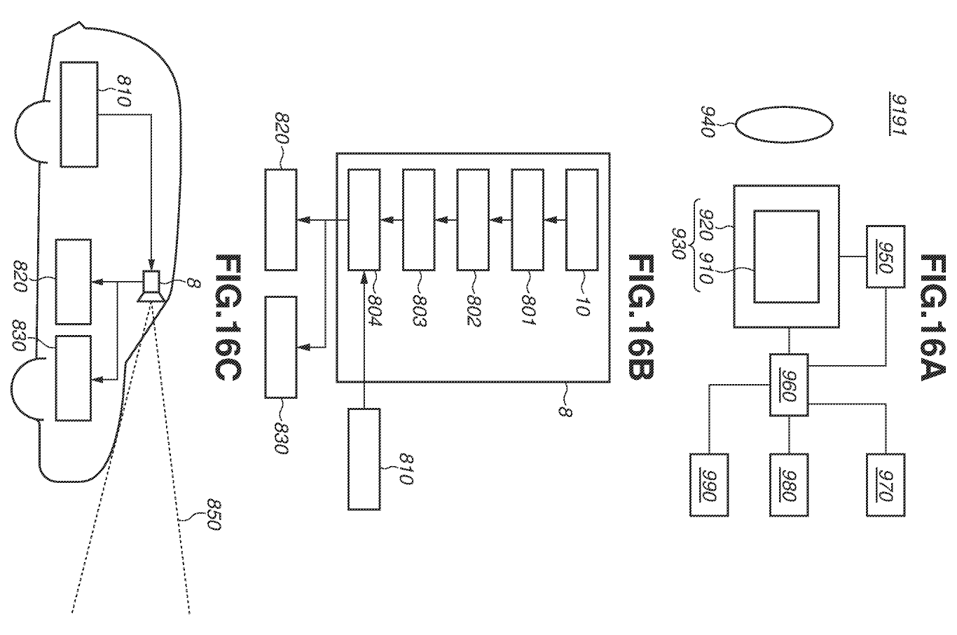

A fourth embodiment can be applied to the first to third embodiments. FIG. 16A is a schematic diagram for describing equipment 9191 including a semiconductor apparatus 930 according to the present embodiment. The photoelectric conversion apparatuses according to the foregoing embodiments can be used as the semiconductor apparatus 930. The equipment 9191 including the semiconductor apparatus 930 will be described in detail. The semiconductor apparatus 930 can include a semiconductor device 910. Aside from the semiconductor device 910, the semiconductor apparatus 930 can include a package 920 accommodating the semiconductor device 910. The package 920 can include a base to which the semiconductor device 910 is fixed, and a glass or other lid opposed to the semiconductor device 910. The package 920 can further include bonding members, such as bonding wires and bumps, for connecting terminals disposed on the base and terminals disposed on the semiconductor device 910.

The equipment 9191 can include at least one of an optical apparatus 940, a control apparatus 950, a processing apparatus 960, a display apparatus 970, a storage apparatus 980, and a mechanical apparatus 990. The optical apparatus 940 is compatible with the semiconductor apparatus 930. The optical apparatus 940 is a lens, a shutter, or a mirror, for example, and includes an optical system for guiding light to the semiconductor apparatus 930. The control apparatus 950 controls the semiconductor apparatus 930. Examples of the control apparatus 950 include a semiconductor apparatus such as an application-specific integrated circuit (ASIC).

The processing apparatus 960 processes signals output from the semiconductor apparatus 930. The processing apparatus 960 is a semiconductor apparatus for constituting an analog front end (AFE) or digital front end (DFE). Examples include a central processing unit (CPU) and an ASIC. The display apparatus 970 is an electroluminescence (EL) display apparatus or a liquid crystal display apparatus that displays information (image) obtained by the semiconductor apparatus 930. The storage apparatus 980 is a magnetic device or semiconductor device that stores the information (image) obtained by the semiconductor apparatus 930. The storage apparatus 980 is a volatile memory such as a static random access memory (SRAM) and a DRAM, or a nonvolatile memory such as a flash memory and a hard disk drive.

The mechanical apparatus 990 includes a movable unit or propelling unit such as a motor and an engine. The equipment 9191 displays signals output from the semiconductor apparatus 930 on the display apparatus 970, or transmits the signals to the outside using a communication apparatus (not illustrated) included in the equipment 9191. For that purpose, the equipment 9191 desirably includes the storage apparatus 980 and the processing apparatus 960 aside from a storage circuit and calculation circuit included in the semiconductor apparatus 930. The mechanical apparatus 990 may be controlled based on the signals output from the semiconductor apparatus 930.

The equipment 9191 is suitable for electronic equipment such as information terminals having an imaging function (for example, smartphones and wearable terminals) and cameras (for example, interchangeable-lens cameras, compact cameras, video cameras, and surveillance cameras). The mechanical apparatus 990 in a camera can drive parts of the optical apparatus 940 for zooming, focusing, and shutter operations. Alternatively, the mechanical apparatus 990 in a camera can move the semiconductor apparatus 930 for image stabilization operation.

The equipment 9191 may be transportation equipment such as a vehicle, ship, and aircraft. The mechanical apparatus 990 in the transportation equipment can be used as a moving apparatus. The equipment 9191 as transportation equipment is suitable for that which transports the semiconductor apparatus 930 and that which assists and/or automatizes driving (manipulation) using an imaging function. A processing apparatus 960 for assisting or automatizing driving (manipulation) can perform processing for operating the mechanical apparatus 990 serving as a moving apparatus, based on information obtained by the semiconductor apparatus 930. Alternatively, the equipment 9191 may be medical equipment such as an endoscope, measurement equipment such as a ranging sensor, analytical equipment such as an electron microscope, office equipment such as a copying machine, and industrial equipment such as a robot.

According to the present embodiment described above, favorable pixel characteristics can be obtained. This enables enhancement in the value of the semiconductor apparatus 930. As employed herein, enhancement in value refers to at least one of the following: additional functions, improved performance, improved characteristics, improved reliability, higher manufacturing yield, reduced environmental impact, reduced cost, smaller size, and lighter weight.

The use of the semiconductor apparatus 930 according to the present embodiment for the equipment 9191 can thus improve the value of the equipment 9191 as well. For example, the semiconductor apparatus 930 can be mounted on transportation equipment to obtain excellent performance in capturing images outside the transportation equipment or measuring the external environment. In manufacturing and selling the transportation equipment, the decision to incorporate the semiconductor apparatus 930 according to the present embodiment in the transportation equipment is therefore advantageous for improving the performance of the transportation equipment itself. In particular, the semiconductor apparatus 930 is suitable for transportation equipment that performs driving assistance and/or automatic driving thereof using information obtained by the semiconductor apparatus 930.

A photoelectric conversion system and a moving body according to the present embodiment will be described with reference to FIGS. 16B and 16C.

FIG. 16B illustrates an example of a photoelectric conversion system related to an in-vehicle camera. A photoelectric conversion system 8 includes a photoelectric conversion apparatus 10. The photoelectric conversion apparatus 10 is a photoelectric conversion apparatus (imaging apparatus) according to one of the foregoing first to third embodiments. The photoelectric conversion system 8 includes an image processing unit 801 that performs image processing on a plurality of pieces of image data acquired by the photoelectric conversion apparatus 10, and a parallax acquisition unit 802 that calculates a parallax (phase difference between parallax images) from the plurality of pieces of image data acquired by the photoelectric conversion system 8. Here, the photoelectric conversion system 8 may include a not-illustrated optical system for guiding light to the photoelectric conversion apparatus 10, such as a lens, a shutter, and a mirror. A plurality of photoelectric conversion units substantially conjugate with the pupil of the optical system may be disposed on pixels of the photoelectric conversion apparatus 10. For example, a plurality of photoelectric conversion units substantially conjugate with the pupil may be disposed corresponding to a microlens. The plurality of photoelectric conversion units receives light beams transmitted through respective different positions of the pupil of the optical system, and the photoelectric conversion apparatus 10 outputs pieces of image data corresponding to the light beams transmitted through the different positions. The parallax acquisition unit 802 may calculate the parallax using the pieces of output image data. The photoelectric conversion system 8 also includes a distance acquisition unit 803 that calculates a distance to an object based on the calculated parallax, and a collision determination unit 804 that determines whether there is a possibility of collision based on the calculated distance. The parallax acquisition unit 802 and the distance acquisition unit 803 are examples of a distance information acquisition unit for acquiring distance information about an object. In other words, distance information refers to information about the parallax, a defocus amount, and/or the distance to the object. The collision determination unit 804 may determine the possibility of collision using any of these pieces of distance information. The distance information may be acquired using ToF. The distance information acquisition unit may be implemented by dedicatedly designed hardware or a software module. A field-programmable gate array (FPGA) or ASIC may be used for implementation. The distance information acquisition unit may be implemented by a combination of these.

The photoelectric conversion system 8 is connected to a vehicle information acquisition apparatus 810, and can acquire vehicle information such as a vehicle speed, yaw rate, and steering angle. The photoelectric conversion system 8 is also connected to an electronic control unit (ECU; hereinafter, referred to as a control ECU) 820. The control ECU 820 is a control apparatus that outputs a control signal for generating braking force on the vehicle based on the determination result of the collision determination unit 804. The photoelectric conversion system 8 is also connected to an alarm apparatus 830 that issues an alarm to the driver based on the determination result of the collision determination unit 804. For example, if the determination result of the collision determination unit 804 indicates a high possibility of collision, the control ECU 820 performs vehicle control to avoid the collision or reduce damage by applying brakes, releasing the accelerator, and/or reducing the engine output. The alarm apparatus 830 warns the user by sounding an alarm, displaying alarm information on the screen of a car navigation system, and/or vibrating the seatbelt or steering wheel.

In the present embodiment, the photoelectric conversion system 8 captures images near the vehicle, such as in front of or behind the vehicle.

FIG. 16C illustrates the photoelectric conversion system 8 in the case of capturing images in front of the vehicle (imaging range 850). The vehicle information acquisition apparatus 810 sends instructions to the photoelectric conversion system 8 or the photoelectric conversion apparatus 10. Such a configuration can improve the accuracy of distance measurement.

While an example of control to avoid collision with other vehicles has been described above, the photoelectric conversion system 8 can also be applied to automatic driving control to follow another vehicle and automatic driving control to stay in the lane. Moreover, the photoelectric conversion system 8 is not limited to vehicles such as an automobile, and can be applied to a moving body (moving apparatus) such as a ship, aircraft, and industrial robot. This moving body includes either one or both a driving force generation unit that generates driving force mainly used to move the moving body and a rotating body mainly used to move the moving body. The driving force generation unit can be an engine or a motor. The rotating body can be a tire, wheel, ship screw, or propeller. The photoelectric conversion system 8 is not limited to moving bodies, either, and can be widely applied to equipment that uses object recognition, including an intelligent transportation system (ITS).

### (Modifications)

The present invention is not limited to the foregoing embodiments, and various modifications can be made.

For example, examples where one or more parts of the configuration of one of the embodiments is added to another embodiment and examples where a part of the configuration of one of the embodiments is replaced with a part of the configuration of another embodiment are also included in embodiments.

The equipment described in the foregoing fourth embodiment merely demonstrates examples of the photoelectric conversion system to which the photoelectric conversion apparatus can be applied. The equipment and the photoelectric conversion systems to which a photoelectric conversion apparatus according to the present disclosure can be applied are not limited to the configurations illustrated in FIGS. 16A to 16C.

The foregoing embodiments are all merely examples of implementations for carrying out the present disclosure, and the technical scope of the present invention should not be interpreted as solely limited thereto. In other words, the present disclosure can be practiced in various forms without departing from the technical concept or main features thereof.

The embodiments described above can be modified as appropriate without departing from the technical concept. The disclosure of this specification includes not only what is described in this specification, but also all that can be understood from this specification and the drawings attached to this specification. Moreover, the disclosure of this specification includes the complement of the concepts described in this specification. More specifically, if, for example, this specification includes a description stating "A is greater than B", this specification can be said to disclose that "A is not greater than B" even with the description stating "A is not greater than B" omitted. The reason is that when stating "A is greater than B", it is predicated on having considered the case where "A is not greater than B".

The present disclosure is directed to providing a technique advantageous for improving the imaging performance of a photoelectric conversion apparatus having a voltage-holding global electronic shutter function.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-123115, filed July 30, 2024, which is hereby incorporated by reference herein in its entirety.

What is claimed is:

1. A photoelectric conversion apparatus comprising:
a plurality of pixels; and
a processing circuit configured to process signals read from the plurality of pixels,
wherein each pixel of the plurality of pixels includes:
a photoelectric conversion element,
a first amplification unit including an input node to which a signal from the photoelectric conversion element is input, the first amplification unit being configured to output a signal obtained by amplifying a signal level of the input node,
a holding capacitor section configured to hold the output signal of the first amplification unit and have a variable capacitance, and
a second amplification unit including a second input node to which a signal output from the holding capacitor section is input, the second amplification unit being configured to output a signal obtained by amplifying a signal level of the second input node,
wherein the capacitance of the holding capacitor section is changed based on a change in driving power of at least one of the first and second amplification units.

2. A photoelectric conversion apparatus comprising:
a plurality of pixels; and
a processing circuit configured to process signals read from the plurality of pixels,
wherein each pixel of the plurality of pixels includes
a photoelectric conversion element,
a first amplification unit including an input node to which a signal from the photoelectric conversion element is input, the first amplification unit being configured to output a signal obtained by amplifying a signal level of the input node, and
a holding capacitor section connected to the first amplification unit via a switch and configured to hold the output signal of the first amplification unit and have a variable capacitance, and
wherein the capacitance of the holding capacitor section is changed based on a change in an on period of the switch.

3. The photoelectric conversion apparatus according to claim 2, wherein each pixel of the plurality of pixels includes a second amplification unit including a second input node to which a signal output from the holding capacitor section is input, the second amplification unit being configured to output a signal obtained by amplifying a signal level of the second input node.

4. The photoelectric conversion apparatus according to claim 1, wherein the driving power of the first amplification unit is lower than he driving power of the second amplification unit.

5. The photoelectric conversion apparatus according to claim 1,
wherein the photoelectric conversion element is disposed in a first substrate, and the holding capacitor section is disposed in a second substrate, and
wherein the first substrate and the second substrate are stacked.

6. The photoelectric conversion apparatus according to claim 1, wherein the holding capacitor section includes a combination of a plurality of capacitive elements.

7. The photoelectric conversion apparatus according to claim 6, wherein the plurality of capacitive elements is capacitors formed in a wiring structure.

8. The photoelectric conversion apparatus according to claim 6, wherein the plurality of capacitive elements is capacitors formed on a silicon substrate.

9. The photoelectric conversion apparatus according to claim 6, wherein the plurality of capacitive elements has respective different capacitances.

10. The photoelectric conversion apparatus according to claim 9, wherein the holding capacitor section is formed by selecting and connecting capacitive elements having different capacitances.

11. The photoelectric conversion apparatus according to claim 6, wherein the holding capacitor section includes the plurality of capacitive elements not juxtaposed to each other.

12. The photoelectric conversion apparatus according to claim 1,
wherein the processing circuit is configured to perform gain processing, and
wherein the capacitance of the holding capacitor section is changed depending on the gain processing.

13. The photoelectric conversion apparatus according to claim 1, wherein the capacitance of the holding capacitor section is changed depending on a reading mode.

14. The photoelectric conversion apparatus according to claim 1, wherein the driving power of the first amplification unit is variable.

15. The photoelectric conversion apparatus according to claim 1, further comprising a switch configured to reset the holding capacitor section,
wherein at least either a size of the switch or a time to turn the switch on is changed based on the capacitance of the holding capacitor section.

16. The photoelectric conversion apparatus according to claim 1, wherein the capacitance is increased based on an increase in driving power of at least one of the first and second amplification units.

17. The photoelectric conversion apparatus according to claim 1,
wherein a current source is connected to the first amplification unit via a transistor, and
wherein the driving power of the first amplification unit is changed by changing a voltage to be applied to a gate of the transistor.

18. The photoelectric conversion apparatus according to claim 1,
wherein a plurality of current sources is connected to the first amplification unit in parallel, and
wherein the driving power of the first amplification unit is changed by changing a number of current sources connected among the plurality of current sources.

19. The photoelectric conversion apparatus according to claim 1,
wherein a first current source transistor and a second current source transistor are connected to the first amplification unit, and
wherein the first current source transistor has a gate width greater than a gate width of the second current source transistor.

20. Equipment comprising:
the photoelectric conversion apparatus according to claim 1; and
at least one of
an optical apparatus compatible with the photoelectric conversion apparatus,
a control apparatus configured to control the photoelectric conversion apparatus,
a processing apparatus configured to process a signal output from the photoelectric conversion apparatus,
a display apparatus configured to display information obtained by the photoelectric conversion apparatus,
a storage apparatus configured to store the information obtained by the photoelectric conversion apparatus, and
a mechanical apparatus configured to operate based on the information obtained by the photoelectric conversion apparatus.
